(19) United States
(12) Patent Application Publication
(10) Pub. No.: US 2026/0047466 A1
(43) Pub. Date: Feb. 12, 2026

(54) BONDING APPARATUS AND METHOD OF BONDING SEMIOCONDUCTOR CHIPS

(71) Applicant: Taiwan Semiconductor Manufacturing Company, Ltd., Hsinchu (TW)

(72) Inventors: Yu-Sheng Lin, Taichung City (TW); Yang-Chih Hsueh, Hsinchu City (TW); Yan-Zuo Tsai, Hsinchu City (TW); Yung-Chi Lin, New Taipei City (TW); Yen-Ming Chen, Hsin-Chu County (TW)

(73) Assignee: Taiwan Semiconductor Manufacturing Company, Ltd., Hsinchu (TW)

(21) Appl. No.: 18/795,208

(22) Filed: Aug. 6, 2024

(51) Int. Cl. H01L 23/00

(52) U.S. Cl. CPC H01L 24/74; H01L 24/80; H01L 2224/74; H01L 2224/80075; H01L 2224/80894; H01L 2924/37001; H01L 2924/40

(57) ABSTRACT

A bonding apparatus includes a chuck table, a gantry frame, a bond head and a gas supplying mechanism. The chuck table is configured to support a semiconductor wafer. The gantry frame is disposed over the chuck table. The bond head is movably installed on the gantry frame, wherein the bond head is configured to pick up a semiconductor chip from a support structure, and for moving the semiconductor chip towards the chuck table for bonding to the semiconductor wafer. The gas supplying mechanism is configured to supply a bonding gas to the semiconductor wafer during the bonding of the semiconductor chip.

### BACKGROUND

In recent years, the semiconductor industry has experienced rapid growth due to continuous improvement in integration density of various electronic components, e.g., transistors, diodes, resistors, capacitors, etc. For the most part, this improvement in integration density has come from successive reductions in minimum feature size, which allows more components to be integrated into a given area. As the demand for miniaturization, higher speed and greater bandwidth, as well as lower power consumption and latency has grown recently, there has grown a need for smaller and more creative packaging techniques of semiconductor dies. In the course of advancement and innovation, the formation of semiconductor devices usually involves bonding of two or more semiconductor wafers together, or bonding two or more semiconductor chips on a semiconductor wafer.

### BRIEF DESCRIPTION OF THE DRAWINGS

Aspects of the disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A to FIG. 6B are schematic sectional, top and bottom views of various stages in a method of bonding semiconductor chips using a bonding apparatus according to some exemplary embodiments of the disclosure.

FIG. 7 to FIG. 9 are schematic sectional views of various stages in a method of bonding semiconductor chips using a bonding apparatus according to some other exemplary embodiments of the disclosure.

FIG. 10 to FIG. 14 are schematic sectional views of various stages in a method of bonding semiconductor chips using a bonding apparatus according to some other exemplary embodiments of the disclosure.

FIG. 15 to FIG. 18 are schematic sectional views of various stages in a method of bonding semiconductor chips using a bonding apparatus according to some other exemplary embodiments of the disclosure.

FIG. 19 to FIG. 20 are schematic sectional views of various stages in a method of bonding semiconductor chips using a bonding apparatus according to some other exemplary embodiments of the disclosure.

FIG. 21A to FIG. 24B are schematic sectional and bottom views of various stages in a method of bonding semiconductor chips using a bonding apparatus according to some other exemplary embodiments of the disclosure.

FIG. 25A to FIG. 27B are schematic sectional and bottom views of various stages in a method of bonding semiconductor chips using a bonding apparatus according to some other exemplary embodiments of the disclosure.

FIG. 28 is a schematic bottom view of a bond head in a bonding apparatus according to some other exemplary embodiments of the disclosure.

FIG. 29A to FIG. 31B are schematic sectional and bottom views of various stages in a method of bonding semiconductor chips using a bonding apparatus according to some other exemplary embodiments of the disclosure.

FIG. 32A and FIG. 32B are schematic sectional and bottom views of a bonding apparatus according to some other exemplary embodiments of the disclosure.

FIG. 33A to FIG. 36 are schematic sectional and bottom views of various stages in a method of bonding semiconductor chips using a bonding apparatus according to some other exemplary embodiments of the disclosure.

FIG. 37A to FIG. 40B are schematic sectional and bottom views of various stages in a method of bonding semiconductor chips using a bonding apparatus according to some other exemplary embodiments of the disclosure.

### DETAILED DESCRIPTION

The following disclosure provides many different embodiments, or examples, for implementing different features of the provided subject matter. Specific examples of components, values, operations, materials, arrangements, or the like, are described below to simplify the disclosure. These are, of course, merely examples and are not intended to be limiting. Other components, values, operations, materials, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

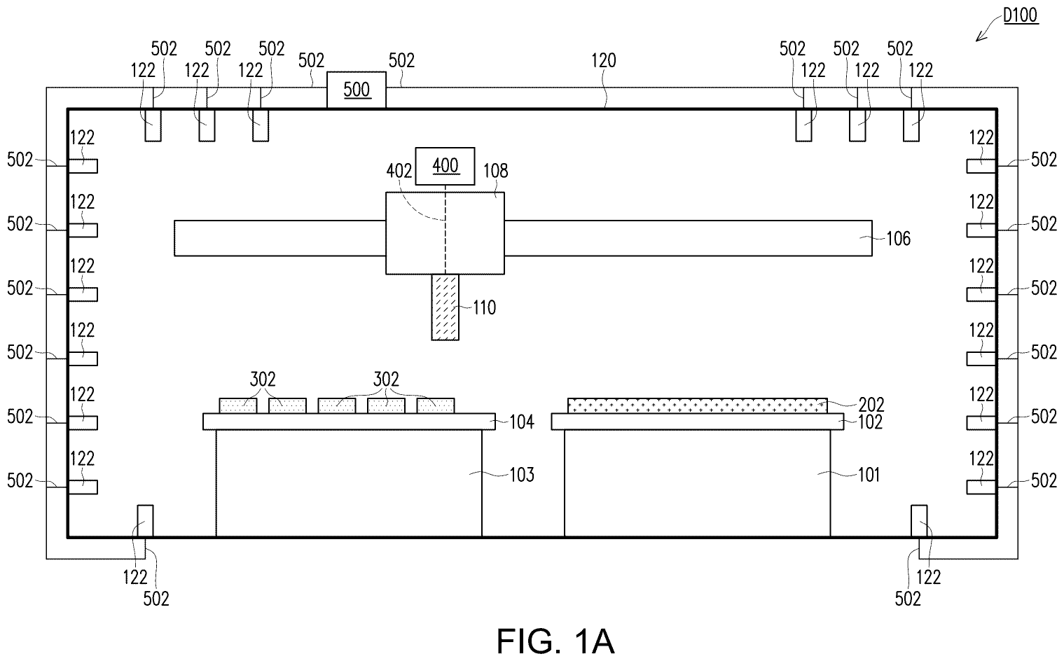

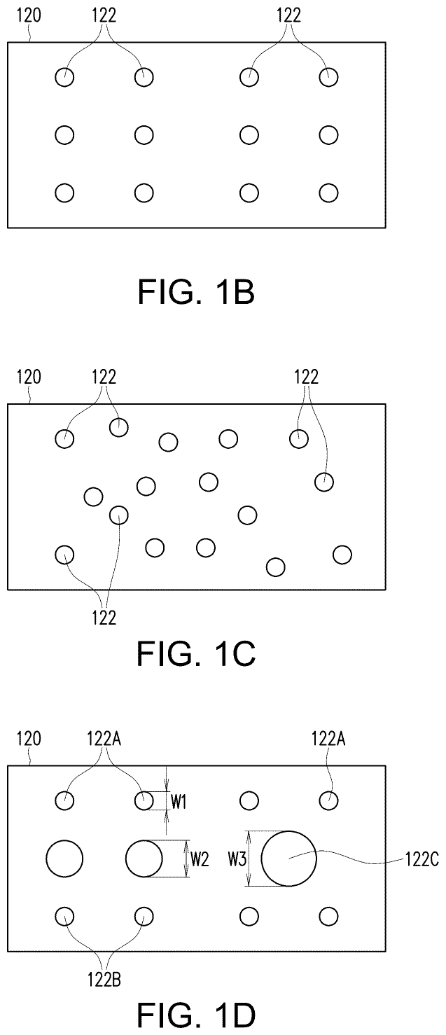

During the bonding of semiconductor chips onto a semiconductor wafer, droplets can usually condensate near the bonding interface with large pressure gradient due to the Joule-Thomson effect. The droplet condensation near the bonding interface may cause tiny bulges at the wafer edge, which in turn result in tiny non-bond issues at the bonding position and cause the formation of large bubbles during further thermal processing. The non-bond defects may further impact the bonding yield in the wafer acceptance testing (WAT). In some embodiments of the present disclosure, a bonding apparatus and a method of bonding semiconductor chips is described, whereby the droplet condensation issue can be resolved, and robust bonding yield can be achieved without the tiny non-bond defects. The various aspects of the present disclosure will now be discussed below with reference to FIG. 1A to FIG. 40B.

FIG. 1A to FIG. 6B are schematic sectional, top and bottom views of various stages in a method of bonding semiconductor chips using a bonding apparatus according to some exemplary embodiments of the disclosure. The method of bonding semiconductor chips of the present disclosure is, for example, a method of bonding semiconductor chips onto a semiconductor wafer, or a chip-on-wafer (CoW) bonding method. Referring to FIG. 1A, in some embodiments, a bonding apparatus D100 is used for bonding semiconductor chips 302 (or semiconductor dies) onto a semiconductor wafer 202.

As illustrated in FIG. 1A, the bonding apparatus D100 includes a chuck table 102, a support structure 104, a gantry frame 106, a guide piece 108, a bond head 110, a gas flow chamber 120, a vacuum device 400 and a gas supplying system 500. In some embodiments, the chuck table 102 is located on a first base 101, and the chuck table 102 is configured to support the semiconductor wafer 202. For example, the chuck table 102 may include a clamping fixture (not shown) or other fixing mechanisms for securing the semiconductor wafer 202 located thereon. In some embodiments, the chuck table 102 includes a driving unit (e.g., motor, controller, and processor, etc.; not shown) for adjusting an x position, a y position, a z position, and/or an angular position of the chuck table 102.

In some embodiments, the support structure 104 is located on a second base 103, and is configured to support a plurality of semiconductor chips 302. The gantry frame 106 is disposed over the chuck table 102 and the support structure 104. Furthermore, the guide piece 108 and the bond head 110 are movably installed on the gantry frame 106. The actions of the bond head 110 and the guide piece 108 may be controlled by a driving unit (e.g., motor, controller, and processor, etc.; not shown), for adjusting an x position, a y position, a z position of the bond head 110. For example, the driving unit of the gantry frame 106 is configured to drive the bond head 110 to the locations between the chuck table 102 and the support structure 104. In some embodiments, the bond head 110 is configured to move downwardly and pick up the semiconductor chips 302 from the support structure 104, and configured to move the semiconductor chips 302 towards the chuck table 102 for bonding to the semiconductor wafer 202.

In some embodiments, the bonding apparatus D100 includes a vacuum device 400 that is configured to supply a vacuum to the bond head 110. For example, the vacuum device 400 is connected to the bond head 110 through one or more pipe structures 402. In certain embodiments, the bond head 110 is configured to pick up the semiconductor chips 302 through the vacuum force supplied from the vacuum device 400. In the exemplary embodiment, although the bond head 110 is described as using the vacuum force for picking up the semiconductor chips 302, it is noted that other pick-up mechanisms may be utilized. For example, in some other embodiments, a bond head including robotic arms or any other grabbing features may be applied for picking up the semiconductor chips 302.

As further illustrated in FIG. 1A, the bonding apparatus D100 includes a gas flow chamber 120, whereby the first base 101, the chuck table 102, the second base 103, the support structure 104, the gantry frame 106, the guide piece 108, the bond head 110, the vacuum device 400 are all located within a space enclosed by the gas flow chamber 120. In some embodiments, a plurality of gas supplying tubes 122 is located on inner surfaces of the gas flow chamber 120. The gas supplying tubes 122 are a type of gas supplying mechanism used in the various bonding apparatus of the present disclosure. In some embodiments, the gas supplying tubes 122 may be located on a top inner surface, a bottom inner surface, or inner side surfaces of the gas flow chamber 120. In the exemplary embodiment, although the gas supplying tubes 122 are illustrated to be arranged in a particular manner, it is noted that the number and position of the gas supplying tubes 122 are not particularly limited, and can be adjusted based on design requirements. For example, in some other embodiments, as long as a bonding gas can be effectively supplied into the gas flow chamber 120, a number of gas supplying tube 122 arranged on the inner surfaces of the gas flow chamber 120 can be one, or more than one.

For example, FIG. 1B to FIG. 1D illustrates top views of the gas supplying tubes 122 arranged on the top inner surface of the gas flow chamber 120 according to various embodiments. As shown in FIG. 1B, in some embodiments, the gas supplying tubes 122 may be arranged in an array on the top inner surface of the gas flow chamber 120. As shown in FIG. 1C, in some other embodiments, the gas supplying tubes 122 may be randomly distributed on the top inner surface of the gas flow chamber 120. As shown in FIG. 1D, in some other embodiments, the gas supplying tubes 122 are distributed on the top inner surface of the gas flow chamber 120, and includes gas supplying tubes 122A having a first width W1, gas supplying tubes 122B having a second width W2, and gas supplying tubes 122C having a third width W3. For example, the third width W3 is greater than the second width W2, while the second width W2 is greater than the first width W1. Although the arrangement of the gas supplying tubes 122 on the top inner surface of the gas flow chamber 120 are illustrated in FIG. 1B to FIG. 1D, it is noted that a similar arrangement of the gas supplying tubes 122 may be applied on the inner side surfaces and the bottom inner surface of the gas flow chamber 120. A total number of the gas supplying tubes 122 located on the top inner surface, the bottom inner surface, and the inner side surfaces of the gas flow chamber 120 is not particularly limited, and may be in a range from one to one hundred.

In some embodiments, the gas supplying tubes 122 are configured to supply a bonding gas that fills up the space in the gas flow chamber 120, and are configured to supply the bonding gas to the semiconductor wafer 202 during the bonding of the semiconductor chips 302. For example, a gas supplying system 500 may be located outside of the gas flow chamber 120, whereby the gas supplying system 500 is connected to each of the gas supplying tubes 122 through a plurality of pipe structures 502. In some embodiments, the gas supplying system 500 is configured for supplying the bonding gas to the gas supplying tubes 122, so that the bonding gas can enter the space inside the gas flow chamber 120 through the gas supplying tubes 122. The supply of the bonding gas to each of the gas supplying tubes 122 may be turned on or turned off through valves (not shown). In some embodiments, the bonding gas assist in the bonding of the semiconductor chips 302 to the semiconductor wafer 202, which will help avoid droplet condensation at the bonding interface. In some embodiments, the bonding gas is helium, or may be other types of low Joule-Thomson coefficient gas that can avoid droplet condensation at the bonding interface.

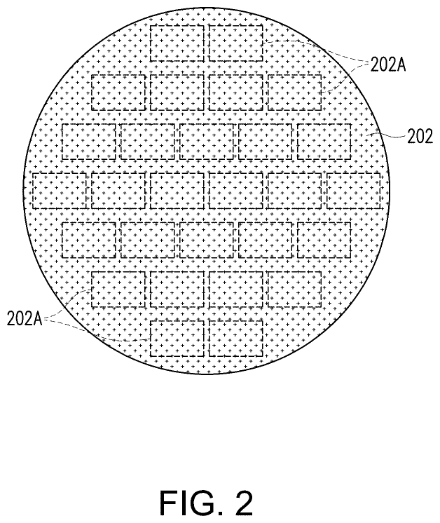

Referring back to FIG. 1A, in the method of bonding semiconductor chips of the present disclosure, a semiconductor wafer 202 is first placed on the chuck table 102 of the bonding apparatus D100, while semiconductor chips 302 are placed on the support structure 104. In some embodiments, the semiconductor wafer 202 includes active devices, passive devices, redistribution layers, one or more conductive elements and dielectric layers formed therein. As further illustrated in FIG. 2, from a top view of the semiconductor wafer 202, the semiconductor wafer 202 includes a plurality of bonding regions 202A, whereby the bonding regions 202A are regions on the semiconductor wafer 202 intended for bonding to the semiconductor chips 302.

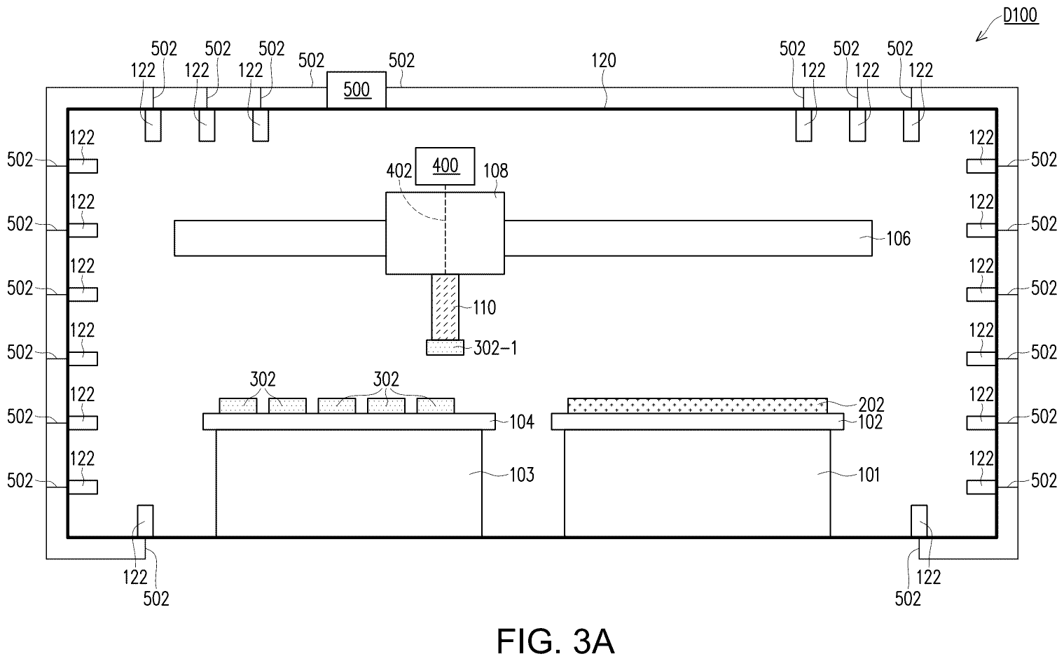

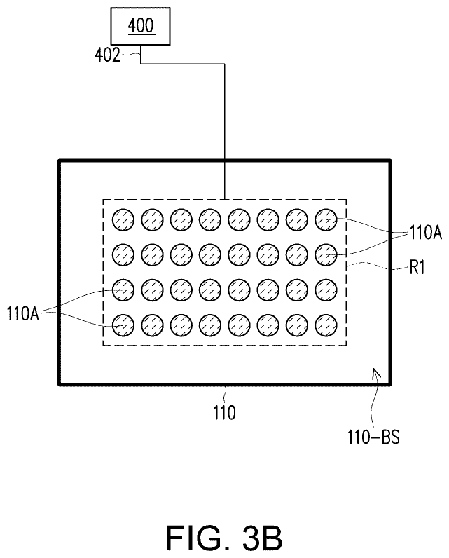

Referring to FIG. 3A to FIG. 5, a picking process and a placing/bonding process of a first semiconductor chip 302-1 (from semiconductor chips 302) using the bonding apparatus D100 is performed. For example, as illustrated in FIG. 3A, the bond head 110 of the bonding apparatus D100 is driven to a position located over the support structure 104 to pick up the first semiconductor chip 302-1 from the support structure 104. As illustrated from a bottom view of the bond head 110 shown in FIG. 3B, the bond head 110 includes a plurality of tube structures 110A located in a center region R1 on a bottom surface 110-BS of the bond head 110. For example, the bottom surface 110-BS of the bond head 110 is the surface that is facing the support structure 104 in FIG. 3A. In some embodiments, the tube structures 110A are connected to the vacuum device 400 through a plurality of pipe structures 402 (one pipe structure 402 is shown for case of illustration). During the picking process, the vacuum device 400 supplies vacuum to each of the tube structures 110A through the pipe structures 402. As such, the tube structures 110A of the bond head 110 can pick up the first semiconductor chip 302-1 in the manner shown in FIG. 3A through the vacuum suction force supplied by the vacuum device 400.

In some embodiments, the gas supplying system 500 is turned on so that a bonding gas (e.g. helium) is supplied into the gas flow chamber 120 through the gas supplying tubes 122 (gas supplying mechanism) during the picking and placing process of the first semiconductor chip 302-1. However, in some other embodiments, the gas supplying system 500 can be turned on at a later stage as long as the bonding gas is flowing through a bonding interface during the bonding of the first semiconductor chip 302-1 to the semiconductor wafer 202. Furthermore, a gas flow of the bonding gas supplied by the gas supplying system 500 is not particularly limited as long as the gas flow rate is greater than an exhaust flow rate of the bonding apparatus D100.

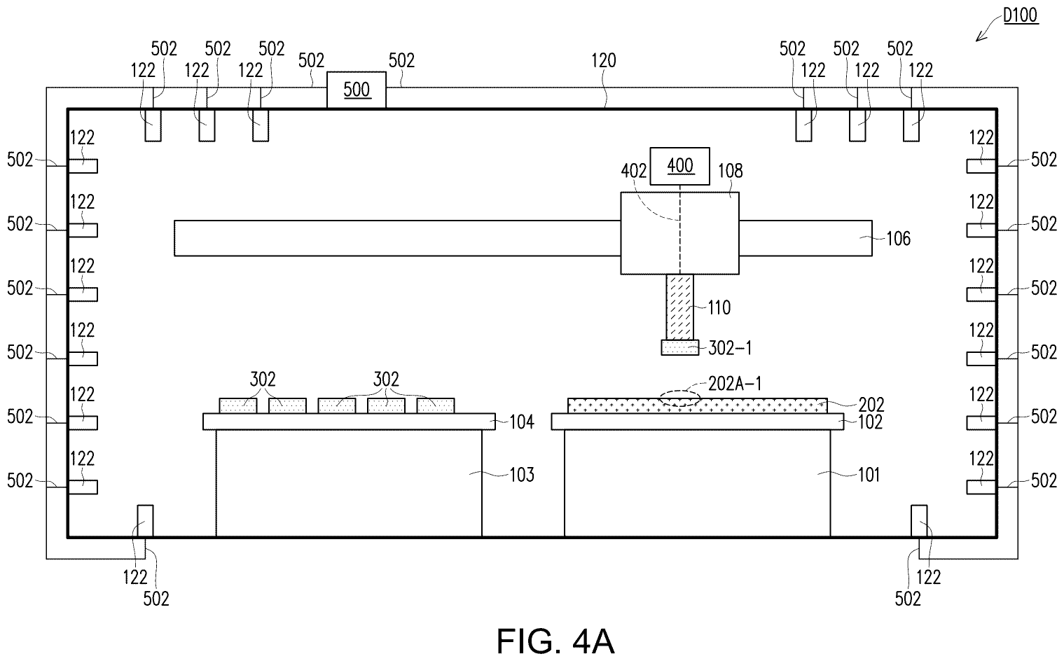

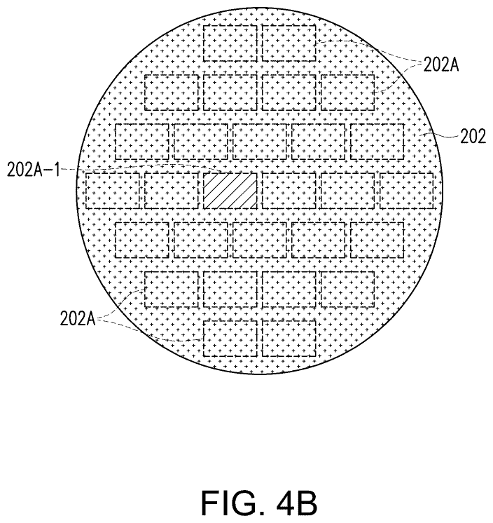

Referring to FIG. 4A and FIG. 4B, in a subsequent step, after picking up the first semiconductor chip 302-1, the bond head 110 is driven for moving the first semiconductor chip 302-1 to a position located over a first bonding region 202A-1 of the semiconductor wafer 202. The position of the first bonding region 202A-1 on the semiconductor wafer 202 is not particularly limited, and may be adjusted based on bonding requirements. Thereafter, as illustrated in FIG. 4A, and from a top view of the semiconductor wafer 202 as shown in FIG. 4B, a bonding process may be performed for bonding the first semiconductor chip 302-1 to the first bonding region 202A-1 of the semiconductor wafer 202. In some embodiments, a bonding temperature of the bonding process is at room temperature, but the disclosure is not limited thereto. In other embodiments, the bonding temperature may be appropriately adjusted based on different bonding requirements.

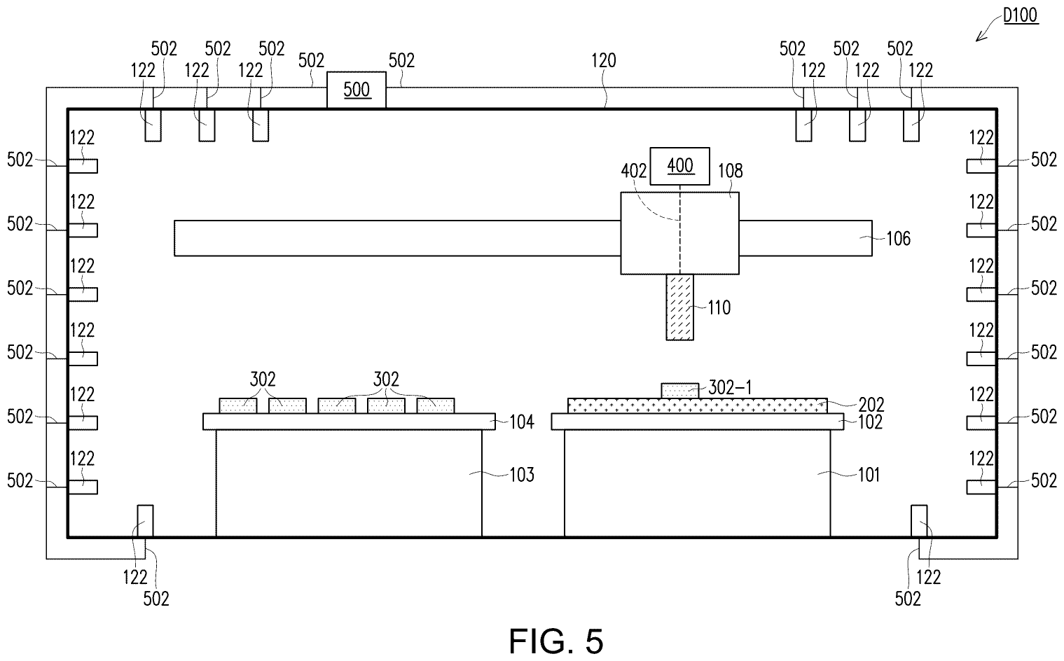

As shown in FIG. 4A, although one bond head 110 is illustrated as an example, there may in fact be more than one bond head 110 installed on the guide piece 108. For example, multiple bond heads 110 may perform a pick-and-place process in turns, and each bond head 110 may be controlled independently from the actions of other bond heads 110. During the bonding process of bonding the first semiconductor chip 302-1 to the first bonding region 202A-1 of the semiconductor wafer 202, a gas flow of the bonding gas through the bonding interface between the first semiconductor chip 302-1 and the semiconductor wafer 202 is ensured to prevent droplet condensation. Thereafter, the first semiconductor chip 302-1 may be bonded to the semiconductor wafer 202 and released from the bond head 110 as shown in FIG. 5. For example, the bond head 110 releases the first semiconductor chip 302-1 by turning off the vacuum supplied from the vacuum device 400.

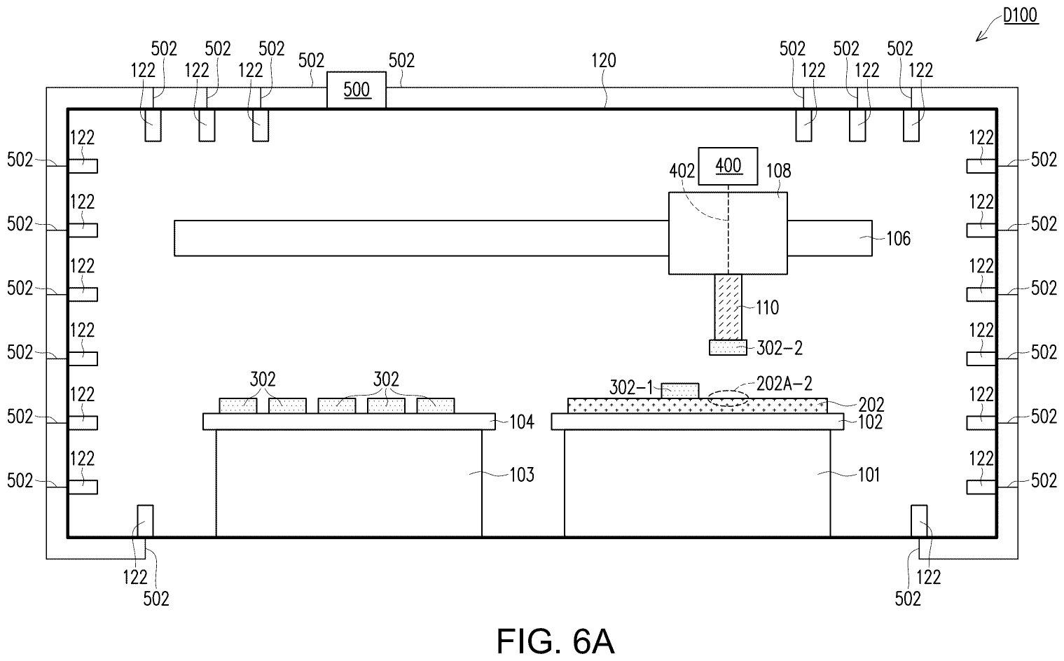

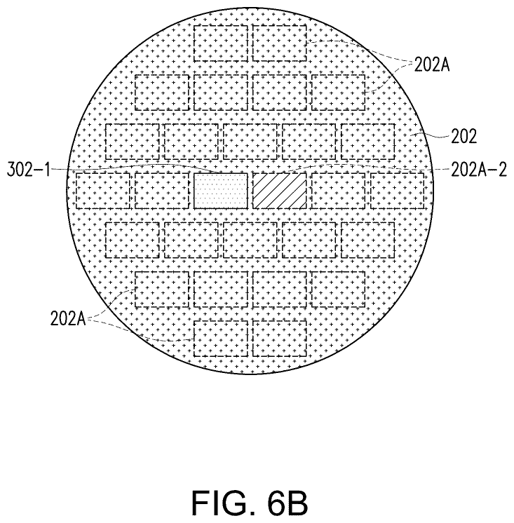

Referring to FIG. 6A and FIG. 6B, in some embodiments, after bonding the first semiconductor chip 302-1 to the first bonding region 202A-1 of the semiconductor wafer 202, a second semiconductor chip 302-2 may then be bonded to a second bonding region 202A-2 of the semiconductor wafer 202 in a similar manner. For example, in some embodiments, the bond head 110 of the bonding apparatus D100 is driven to a position located over the support structure 104 to pick up a second semiconductor chip 302-2 from the support structure 104. Subsequently, the bond head 110 is driven for moving the second semiconductor chip 302-2 to a position located over a second bonding region 202A-2 of the semiconductor wafer 202. Thereafter, a bonding process may be performed for bonding the second semiconductor chip 302-2 to the second bonding region 202A-2 of the semiconductor wafer 202.

In the embodiment shown in FIG. 1A to FIG. 6B, a gas supplying mechanism (gas supplying tubes 122) is provided in the bonding apparatus D100 for supplying a bonding gas to the semiconductor wafer 202 during the bonding of the semiconductor chip 302. The in-situ gas flow ensures that the droplet condensation caused by the Joule-Thomson effect is minimized at the bonding interface. As such, by using the bonding apparatus D100 of the present disclosure for chip-on-wafer bonding, robust bonding yield can be achieved while tiny non-bond defects can be removed.

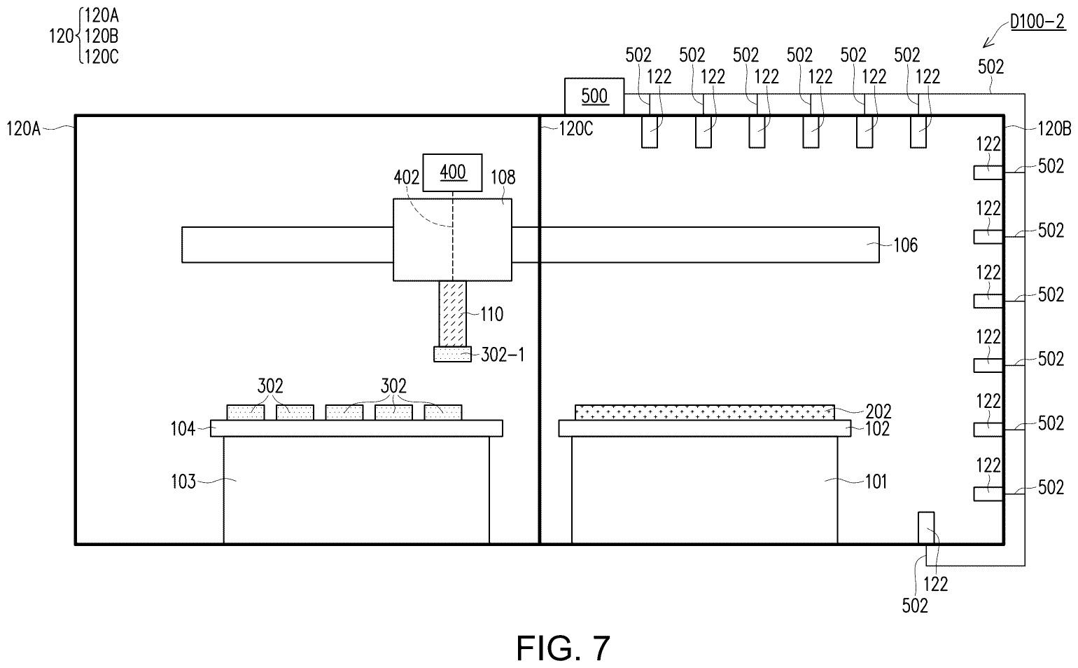

FIG. 7 to FIG. 9 are schematic sectional views of various stages in a method of bonding semiconductor chips using a bonding apparatus according to some other exemplary embodiments of the disclosure. The method illustrated in FIG. 7 to FIG. 9 is similar to the method illustrated in FIG. 1A to FIG. 6B. Therefore, the same reference numerals are used to refer to the same or liked parts, and its detailed description will be omitted herein. The difference between the embodiment shown in FIG. 1A to FIG. 6B and the embodiment shown in FIG. 7 to FIG. 9 is in the design of the gas flow chamber 120.

As illustrated in FIG. 7, in the exemplary embodiment, the bonding apparatus D100-2 includes a gas flow chamber 120, whereby the first base 101, the chuck table 102, the second base 103, the support structure 104, the gantry frame 106, the guide piece 108, the bond head 110, the vacuum device 400 are all located within a space enclosed by the gas flow chamber 120. In certain embodiments, the gas flow chamber 120 includes a first chamber 120A, a second chamber 120B and a movable door 120C located in between the first chamber 120A and the second chamber 120B. The support structure 104 and the second base 103 are located in the first chamber 120A, while the chuck table 102 and the first base 101 are located in the second chamber 120B. In some embodiments, the gas supplying tubes 122 are located on inner surfaces in the second chamber 120B of the gas flow chamber 120, while the first chamber 120A is free of the gas supplying tubes 122. In some embodiments, the gantry frame 106 extends from the first chamber 120A to the second chamber 120B by passing through the movable door 120C. For example, the movable door 120C includes openings that correspond to the dimensions of the gantry frame 106, thus allowing the gantry frame 106 to pass through. In some embodiments, the guide piece 108 and the bond head 110 are movably installed on the gantry frame 106, and are movable between the first chamber 120A and the second chamber 120B. For example, the movable door 120C is configured to be opened and closed allowing the driving of the guide piece 108 and the bond head 110 in between the two chambers.

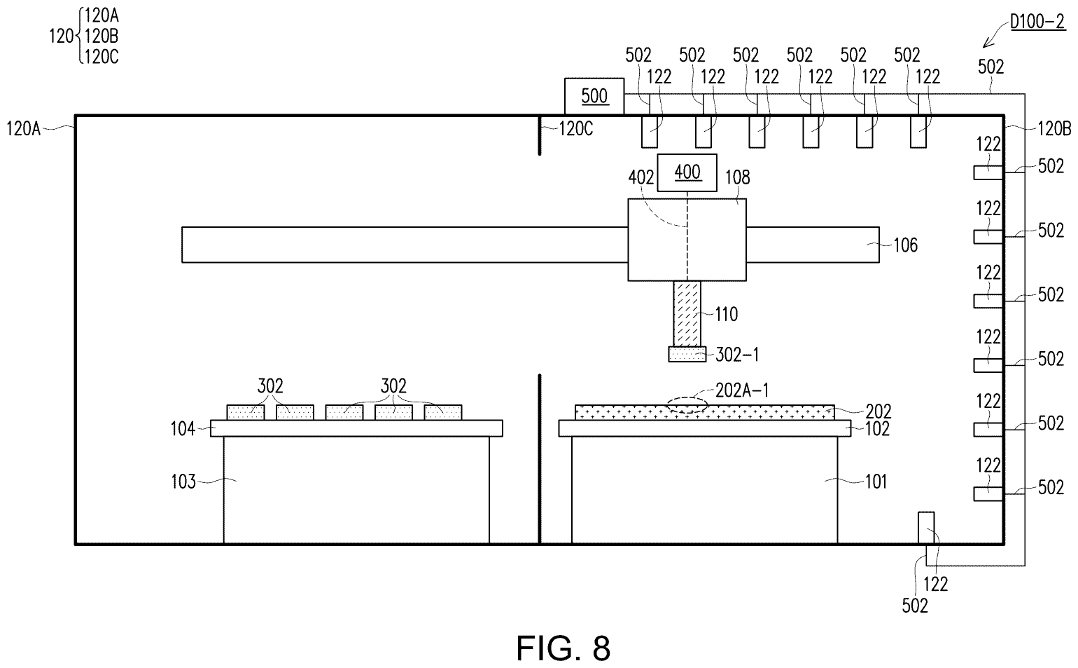

Referring to FIG. 7, in the method of bonding semiconductor chips of the present disclosure, the bond head 110 of the bonding apparatus D100-2 is driven to a position located over the support structure 104 to pick up the first semiconductor chip 302-1 from the support structure 104. Subsequently, referring to FIG. 8, after picking up the first semiconductor chip 302-1, the movable door 120C is opened, and the bond head 110 is driven to pass through the movable door 120C for moving the first semiconductor chip 302-1 to a position located over a first bonding region 202A-1 of the semiconductor wafer 202.

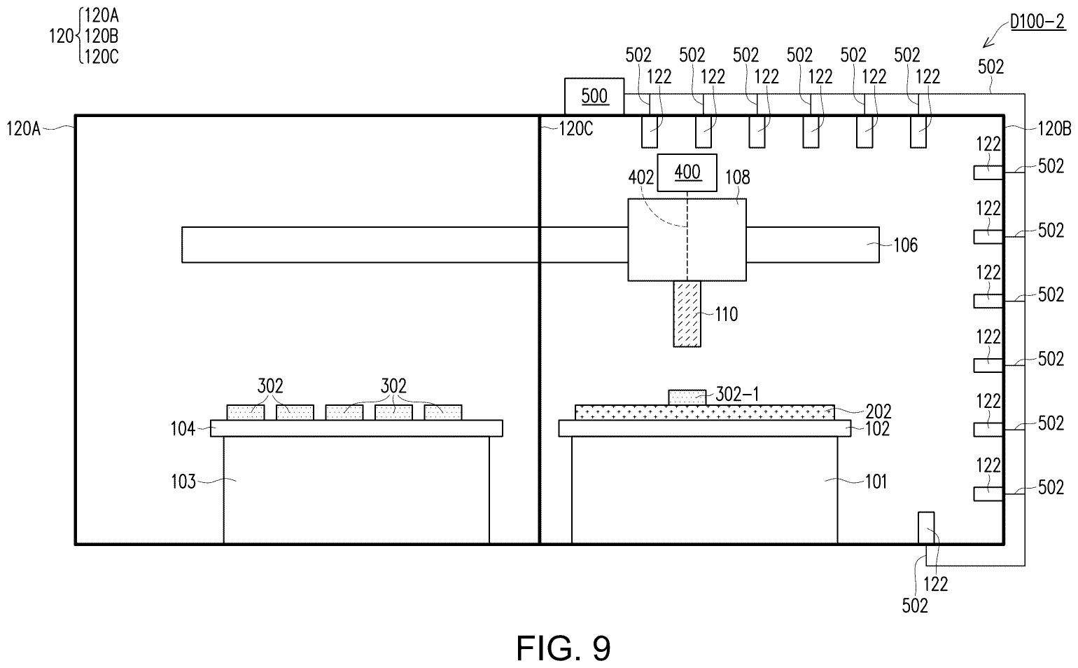

Referring to FIG. 9, in a subsequent step, the gas supplying system 500 is turned on so that a bonding gas (e.g. helium) is supplied into the second chamber 120B of the gas flow chamber 120 through the gas supplying tubes 122 (gas supplying mechanism). Thereafter, the movable door 120C is closed allowing the second chamber 120B to be filled with the bonding gas, and so that the first semiconductor chip 302-1 may be bonded to the semiconductor wafer 202 and released from the bond head 110.

In the embodiment shown in FIG. 7 to FIG. 9, a gas supplying mechanism (gas supplying tubes 122) is provided in the bonding apparatus D100-2 for supplying a bonding gas to the semiconductor wafer 202 during the bonding of the semiconductor chip 302. The in-situ gas flow ensures that the droplet condensation caused by the Joule-Thomson effect is minimized at the bonding interface. As such, by using the bonding apparatus D100-2 of the present disclosure for chip-on-wafer bonding, robust bonding yield can be achieved while tiny non-bond defects can be removed.

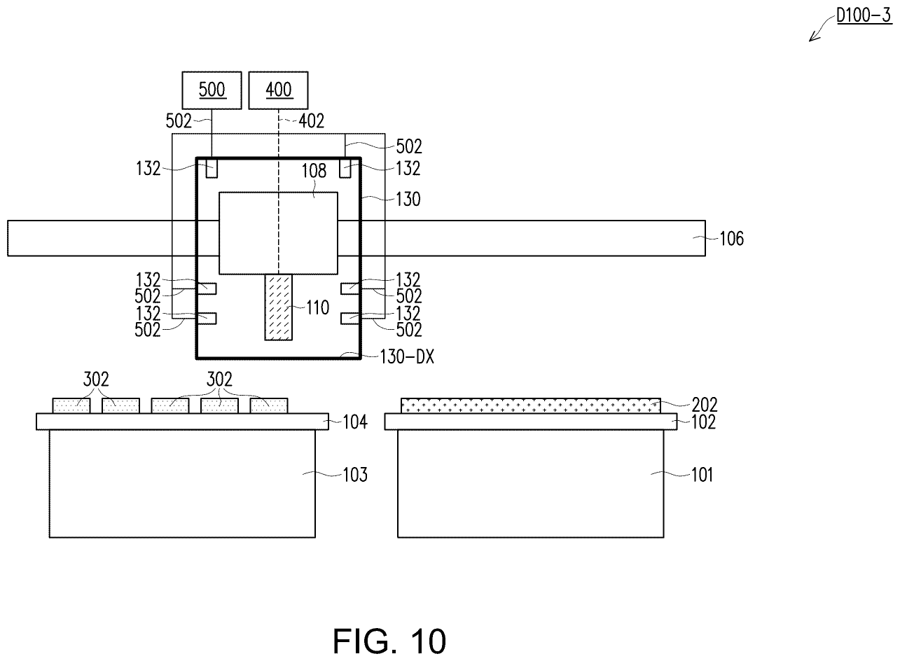

FIG. 10 to FIG. 14 are schematic sectional views of various stages in a method of bonding semiconductor chips using a bonding apparatus according to some other exemplary embodiments of the disclosure. The method illustrated in FIG. 10 to FIG. 14 is similar to the method illustrated in FIG. 1A to FIG. 6B. Therefore, the same reference numerals are used to refer to the same or liked parts, and its detailed description will be omitted herein. The difference between the embodiments is that the gas flow chamber 120 illustrated in FIG. 1A to FIG. 6B is replaced with a cover structure 130 shown in FIG. 10 to FIG. 14.

As illustrated in FIG. 10, in the exemplary embodiment, the bonding apparatus D100-3 includes a cover structure 130. For example, the guide piece 108 and the bond head 110 are located within a space enclosed by the cover structure 130. In some embodiments, the cover structure 130 is slidable along with the guide piece 108 and the bond head 110 on the gantry frame 106. In some embodiments, the cover structure 130 includes a top inner surface, a bottom inner surface, and inner side surfaces joining the top inner surface to the bottom inner surface. In certain embodiments, the cover structure 130 includes a movable door 130-DX located on the bottom inner surface. For example, the movable door 130-DX is configured to be opened and closed allowing the driving of the bond head 110 outside the space of the cover structure 130 when picking up the semiconductor chip 302 from the support structure 104, and during the bonding of the semiconductor chip 302 to the semiconductor wafer 202. In some embodiments, the movable door 130-DX is an automatic door that automatically opens and closes based on a detection of movement of the bond head 110. In some other embodiments, the movable door 130-DX is configured to be opened and closed through receiving commands from a control device. Alternatively, the movable door 130-DX may also be opened and closed manually. As further illustrated in FIG. 10, a plurality of gas supplying tubes 132 is located on the top inner surface and inner side surfaces of the cover structure 130. The gas supplying tubes 132 are a type of gas supplying mechanism used in the various bonding apparatus of the present disclosure.

Although the gas supplying tubes 132 are shown to be arranged in a particular manner, it is noted that the gas supplying tubes 132 may be located at any free position on the top inner surface, the bottom inner surface and inner side surfaces of the cover structure 130. Furthermore, in some embodiments, the gas suppling tubes 132 may be arranged in an array, may be randomly distributed, or may have different widths similar to the arrangement of the gas supplying tubes 122 shown in FIG. 1B to FIG. 1D. In some embodiments, a total number of the gas supplying tubes 132 located on the top inner surface, the bottom inner surface and inner side surfaces of the cover structure 130 is not particularly limited, and may be in a range from one to one hundred.

In the exemplary embodiment, the vacuum device 400 is connected to the bond head 110 through one or more pipe structures 402. For example, the pipe structures 402 passes through the cover structure 130 to be connected to the tube structures 110A (as shown in FIG. 3B) of the bond head 110. In some embodiments, the gas supplying system 500 is located outside of the cover structure 130, and is configured for supplying the bonding gas to the gas supplying tubes 132, so that the bonding gas can enter the space inside the cover structure 130 through the gas supplying tubes 132 to provide localized gas flow.

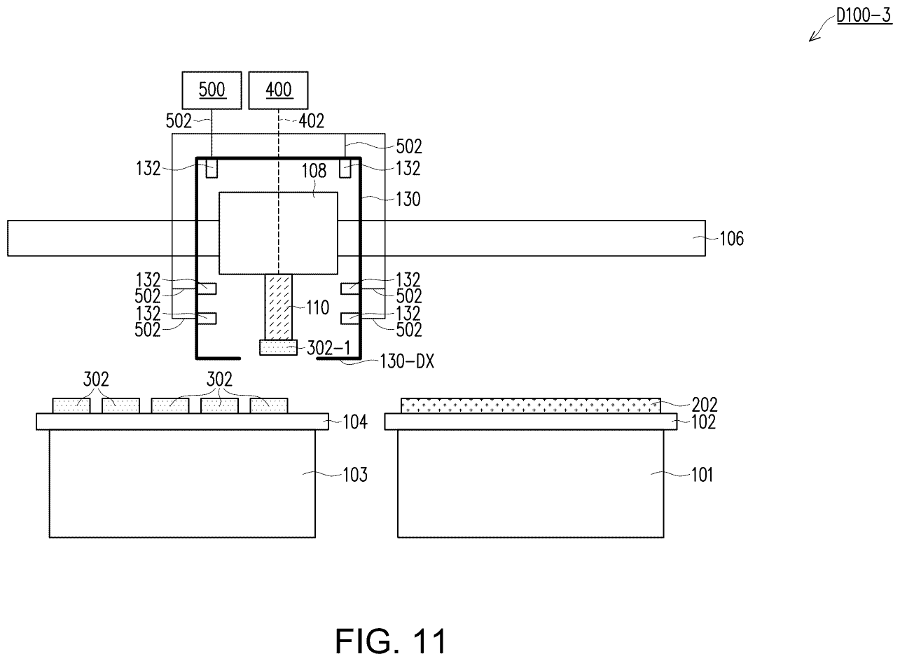

Referring to FIG. 11, in the method of bonding semiconductor chips of the present disclosure, the movable door 130-DX of the cover structure 130 is opened, and the bond head 110 of the bonding apparatus D100-3 is driven to a position located over the support structure 104 to pick up the first semiconductor chip 302-1 from the support structure 104. In some embodiments, the gas supplying system 500 is turned on so that a bonding gas (e.g. helium) is supplied into the cover structure 130 through the gas supplying tubes 132 (gas supplying mechanism) during the picking and placing process of the first semiconductor chip 302-1.

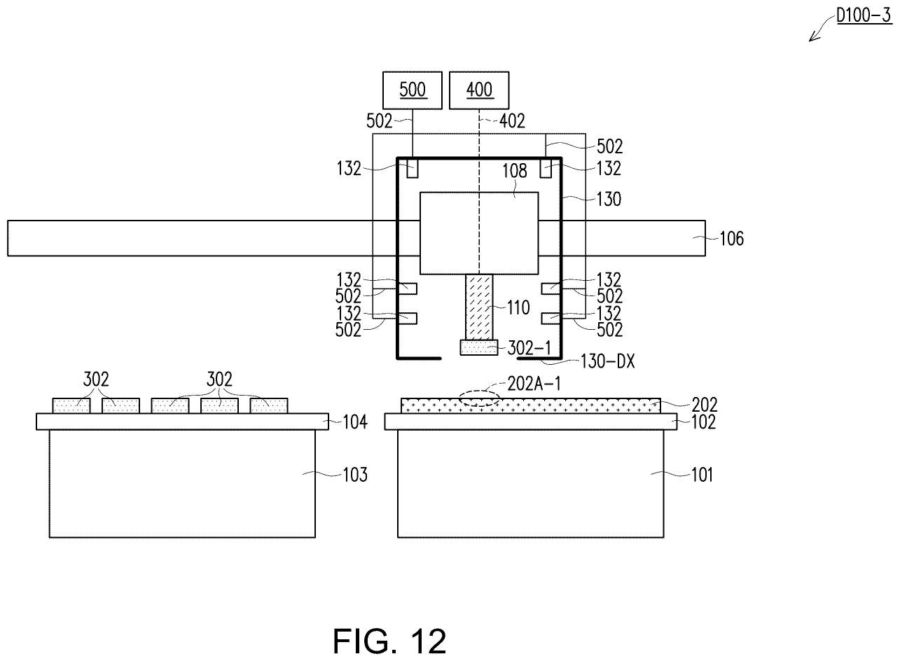

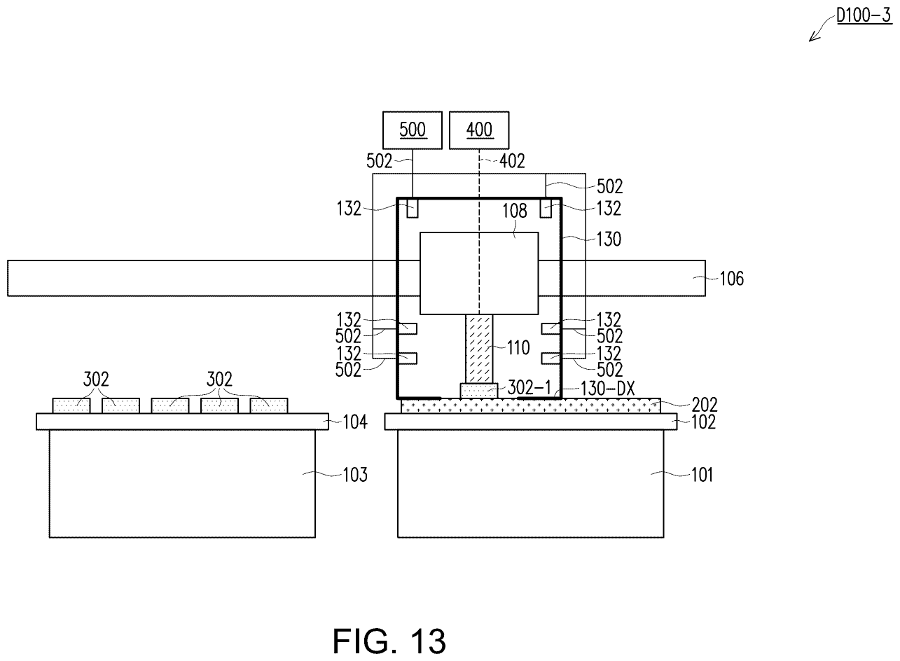

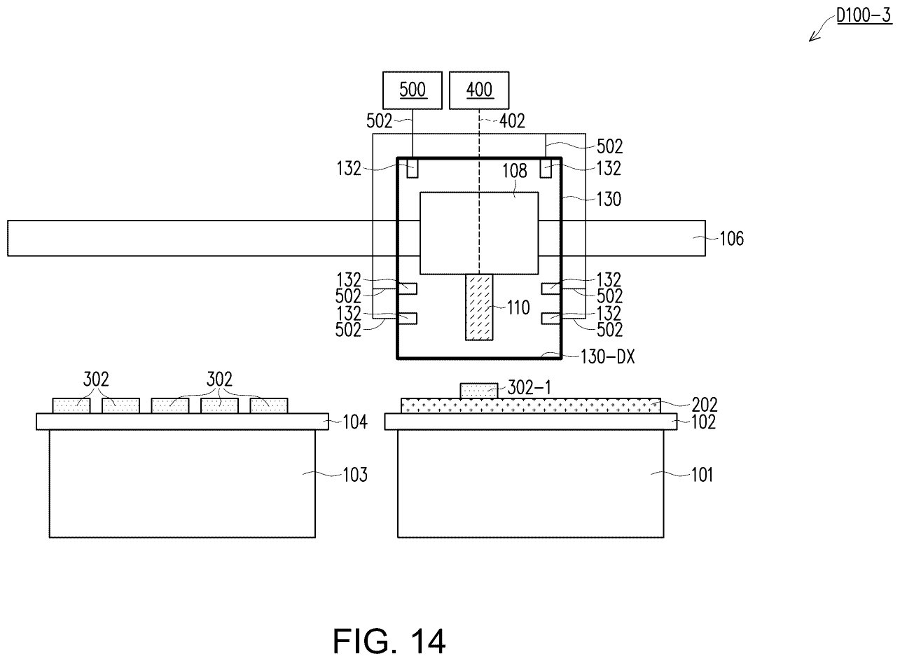

Referring to FIG. 12, in a subsequent step, after picking up the first semiconductor chip 302-1, the bond head 110 is driven for moving the first semiconductor chip 302-1 to a position located over a first bonding region 202A-1 of the semiconductor wafer 202. In some embodiments, the cover structure 130 is moved along with the bond head 110 to be located over the first bonding region 202A-1. Thereafter, referring to FIG. 13, the bond head 110 is moved downwardly so that the first semiconductor chip 302-1 is bonded to the semiconductor wafer 202. At this stage, the bonding gas supplied by the gas supplying system 500 is filling up the space inside the cover structure 130, and is at least flowing through a bonding interface between the first semiconductor chip 302-1 and the semiconductor wafer 202. In some embodiments, to ensure that the bonding gas is flowing through the bonding interface, the outer surface of the movable door 130-DX may come close to a surface of the semiconductor wafer 202, or the outer surface of the movable door 130-DX may be directly contacting the surface of the semiconductor wafer 202. As such, localized gas flow can be provided inside the cover structure 130 and across the bonding interface during the bonding of the first semiconductor chip 302-1 to the semiconductor wafer 202. Referring to FIG. 14, after the first semiconductor chip 302-1 is bonded to the semiconductor wafer 202 and released from the bond head 110, the bond head 110 is retracted back into the cover structure 130, and the movable door 130-DX is closed. Thereafter, the picking and placing process of another semiconductor chip 302 can be performed.

In the embodiment shown in FIG. 10 to FIG. 14, a gas supplying mechanism (gas supplying tubes 132) is provided in the bonding apparatus D100-3 for supplying a bonding gas to the semiconductor wafer 202 during the bonding of the semiconductor chip 302. The in-situ gas flow ensures that the droplet condensation caused by the Joule-Thomson effect is minimized at the bonding interface. As such, by using the bonding apparatus D100-3 of the present disclosure for chip-on-wafer bonding, robust bonding yield can be achieved while tiny non-bond defects can be removed.

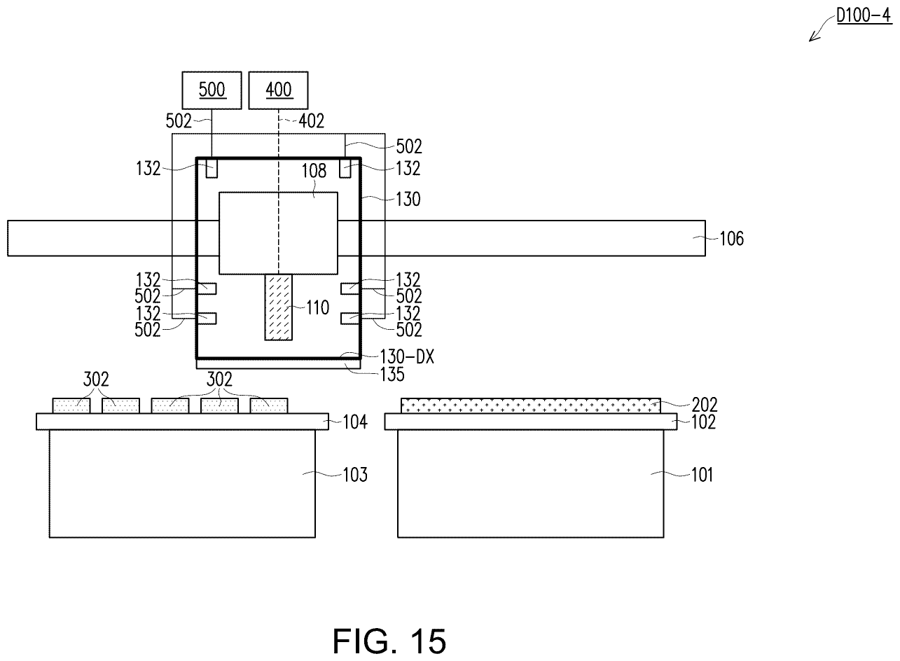

FIG. 15 to FIG. 18 are schematic sectional views of various stages in a method of bonding semiconductor chips using a bonding apparatus according to some other exemplary embodiments of the disclosure. The method illustrated in FIG. 15 to FIG. 18 is similar to the method illustrated in FIG. 10 to FIG. 14. Therefore, the same reference numerals are used to refer to the same or liked parts, and its detailed description will be omitted herein. The difference between the embodiments is that a protection layer 135 is further provided on the cover structure 130 of FIG. 15 to FIG. 18.

As illustrated in FIG. 15, in the exemplary embodiment, the bonding apparatus D100-4 includes a cover structure 130, whereby a protection layer 135 is located on the movable door 130-DX. In the embodiments including the cover structure 130, as the outer surface of the movable door 130-DX may come close to a surface of the semiconductor wafer 202 during the bonding process, a protection layer 135 may be provided on the movable door 130-DX for preventing damage to the semiconductor wafer 202. In some embodiments, the protection layer 135 may be a polymer layer, or may be any other materials that are less likely to cause damage to the surface of the semiconductor wafer 202.

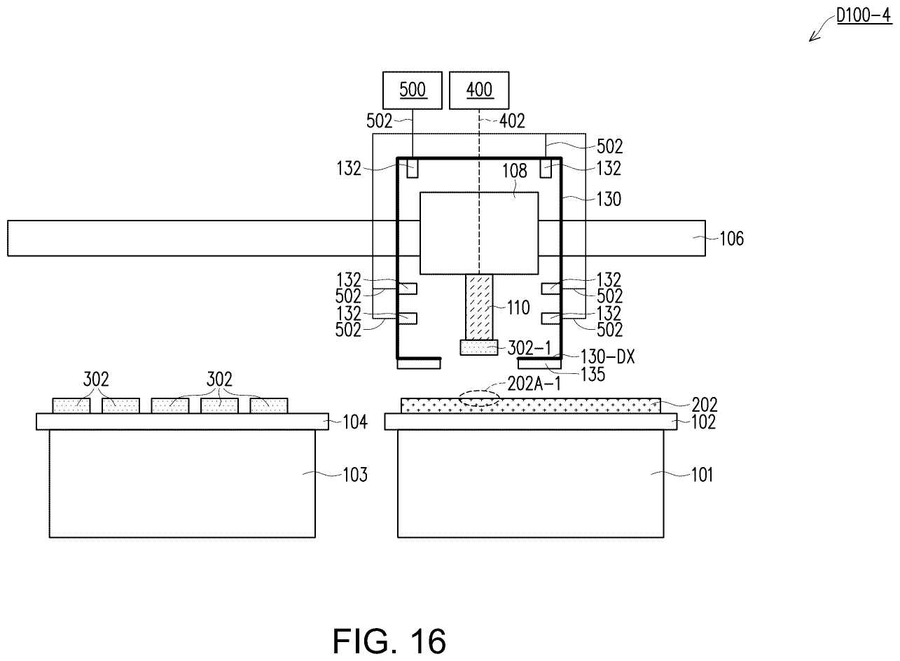

Referring to FIG. 16, in the method of bonding semiconductor chips of the present disclosure, the movable door 130-DX of the cover structure 130 is opened, and the bond head 110 of the bonding apparatus D100-4 is driven to pick up the first semiconductor chip 302-1 from the support structure 104. In the exemplary embodiment, the protection layer 135 is formed on the movable door 130-DX so that it can be opened and closed along with the movable door 130-DX. For example, the protection layer 135 may be formed in separated sections on the movable door 130-DX, and the separated sections may be separated from one another or come into contact with one another when opening or closing the movable door 130-DX. Subsequently, after picking up the first semiconductor chip 302-1, the bond head 110 is driven for moving the first semiconductor chip 302-1 to a position located over a first bonding region 202A-1 of the semiconductor wafer 202. In some embodiments, the gas supplying system 500 is turned on so that a bonding gas (e.g. helium) is supplied into the cover structure 130 through the gas supplying tubes 132 (gas supplying mechanism) during the picking and placing process of the first semiconductor chip 302-1.

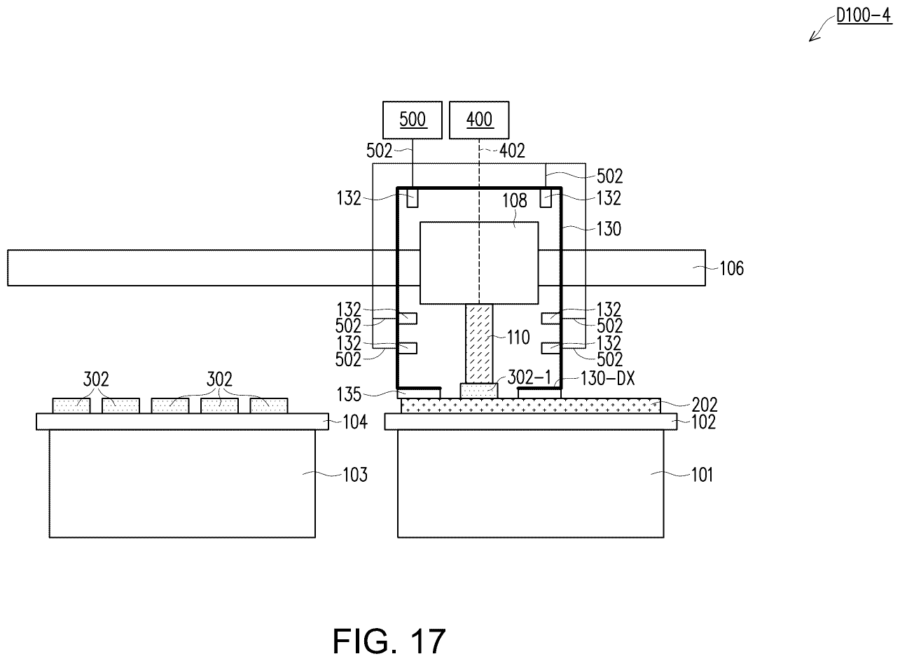

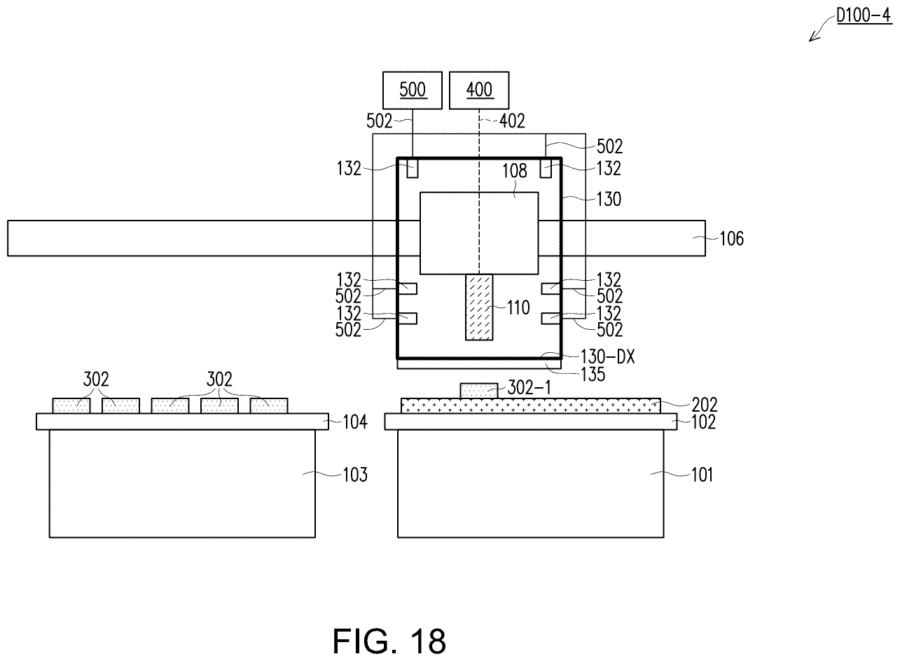

Referring to FIG. 17, in a subsequent step, the bond head 110 is moved downwardly so that the first semiconductor chip 302-1 is bonded to the semiconductor wafer 202. At this stage, the bonding gas supplied by the gas supplying system 500 is filling up the space inside the cover structure 130, and is at least flowing through a bonding interface between the first semiconductor chip 302-1 and the semiconductor wafer 202. In the exemplary embodiment, to ensure that the bonding gas is flowing through the bonding interface, the outer surface of the protection layer 135 is directly contacting the surface of the semiconductor wafer 202. As such, the bonding interface is confined in a space surrounded by the cover structure 130 and the protection layer 135, and localized gas flow can be provided inside the cover structure 130 and across the bonding interface during the bonding of the first semiconductor chip 302-1 to the semiconductor wafer 202. Referring to FIG. 18, after the first semiconductor chip 302-1 is bonded to the semiconductor wafer 202 and released from the bond head 110, the bond head 110 is retracted back into the cover structure 130, and the movable door 130-DX is closed. Thereafter, the picking and placing process of another semiconductor chip 302 can be performed.

In the embodiment shown in FIG. 15 to FIG. 18, a gas supplying mechanism (gas supplying tubes 132) is provided in the bonding apparatus D100-4 for supplying a bonding gas to the semiconductor wafer 202 during the bonding of the semiconductor chip 302. The in-situ gas flow ensures that the droplet condensation caused by the Joule-Thomson effect is minimized at the bonding interface. As such, by using the bonding apparatus D100-4 of the present disclosure for chip-on-wafer bonding, robust bonding yield can be achieved while tiny non-bond defects can be removed.

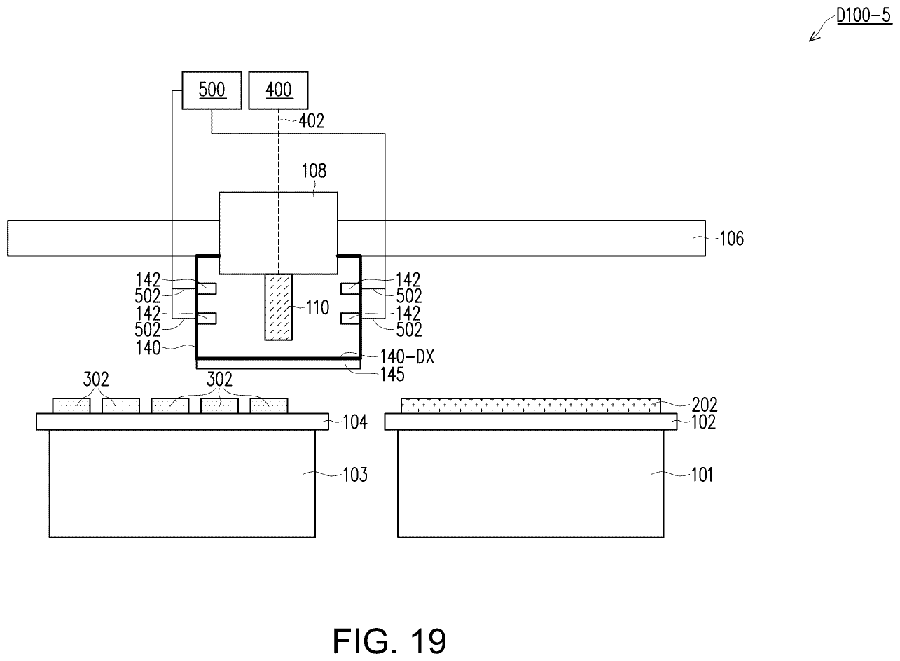

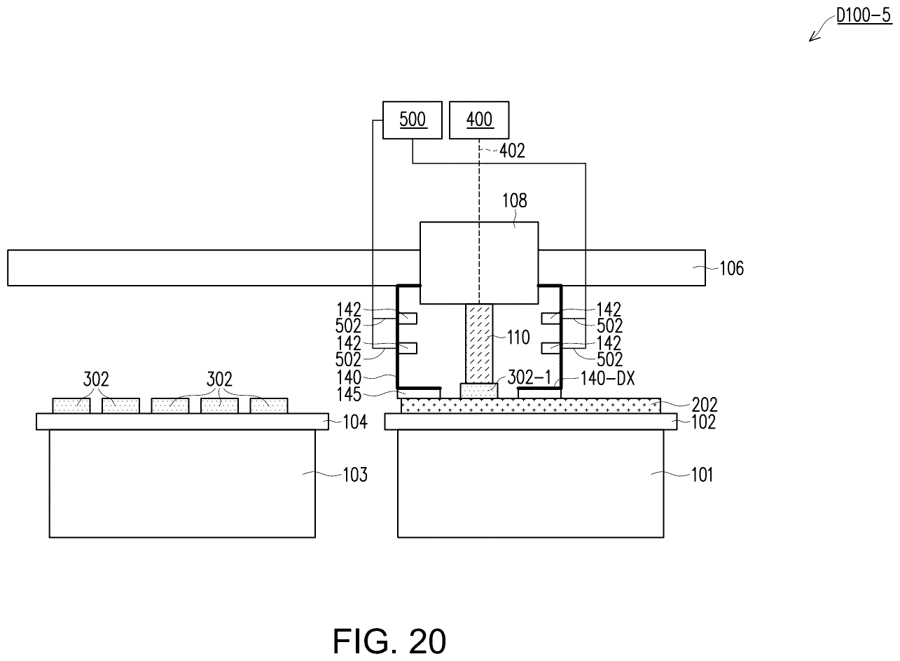

FIG. 19 to FIG. 20 are schematic sectional views of various stages in a method of bonding semiconductor chips using a bonding apparatus according to some other exemplary embodiments of the disclosure. The method illustrated in FIG. 19 to FIG. 20 is similar to the method illustrated in FIG. 15 to FIG. 18. Therefore, the same reference numerals are used to refer to the same or liked parts, and its detailed description will be omitted herein. The difference between the embodiments is that the cover structure 130 is replaced with a cover structure 140.

In the previous embodiments, the guide piece 108 and the bond head 110 are entirely located in the cover structure 130. However, the disclosure is not limited thereto. Referring to FIG. 19, in some embodiments, a cover structure 140 is entirely covering the bond head 110, while the guide piece 108 is partially located in the cover structure 140. In the exemplary embodiment, the cover structure 140 includes a movable door 140-DX located on the bottom inner surface, whereby a protection layer 145 is located on the movable door 140-DX. The movable door 140-DX and the protection layer 145 described herein is similar to the movable door 130-DX and the protection layer 135 described in FIG. 15 to FIG. 18, thus its details will not be repeated herein. As further illustrated in FIG. 19, a plurality of gas supplying tubes 142 is located on the inner side surfaces of the cover structure 140. The gas supplying tubes 142 are a type of gas supplying mechanism used in the various bonding apparatus of the present disclosure.

Although the gas supplying tubes 142 are shown to be arranged in a particular manner, it is noted that the gas supplying tubes 142 may be located at any free position on the top inner surface, the bottom inner surface and inner side surfaces of the cover structure 140. Furthermore, in some embodiments, the gas suppling tubes 142 may be arranged in an array, may be randomly distributed, or may have different widths similar to the arrangement of the gas supplying tubes 122 shown in FIG. 1B to FIG. 1D. In some embodiments, a total number of the gas supplying tubes 142 located on the top inner surface, the bottom inner surface and inner side surfaces of the cover structure 140 is not particularly limited, and may be in a range from one to one hundred.

In the exemplary embodiment, the vacuum device 400 is connected to the bond head 110 through one or more pipe structures 402. For example, the pipe structures 402 passes through the cover structure 140 to be connected to the tube structures 110A (as shown in FIG. 3B) of the bond head 110. In some embodiments, the gas supplying system 500 is located outside of the cover structure 140, and is configured for supplying the bonding gas to the gas supplying tubes 142, so that the bonding gas can enter the space inside the cover structure 140 through the gas supplying tubes 142.

Referring to FIG. 20, in the method of bonding semiconductor chips of the present disclosure, the movable door 140-DX of the cover structure 140 is opened, and the bond head 110 of the bonding apparatus D100-5 is driven to pick up the first semiconductor chip 302-1 from the support structure 104. In the exemplary embodiment, the protection layer 135 is formed on the movable door 130-DX so that it can be opened and closed along with the movable door 130-DX. Subsequently, after picking up the first semiconductor chip 302-1, the bond head 110 is driven for moving the first semiconductor chip 302-1 to a position located over a first bonding region 202A-1 of the semiconductor wafer 202, and the gas supplying system 500 is turned on to supply a bonding gas into the cover structure 140. Thereafter, the bond head 110 is moved downwardly so that the first semiconductor chip 302-1 is bonded to the semiconductor wafer 202. At this stage, the bonding gas supplied by the gas supplying system 500 is filling up the space inside the cover structure 140, and is at least flowing through a bonding interface between the first semiconductor chip 302-1 and the semiconductor wafer 202. After the first semiconductor chip 302-1 is bonded to the semiconductor wafer 202 and released from the bond head 110, the bond head 110 may be retracted back into the cover structure 140, and the movable door 140-DX may be closed. Thereafter, the picking and placing process of another semiconductor chip 302 can be performed.

In the embodiment shown in FIG. 19 to FIG. 20, a gas supplying mechanism (gas supplying tubes 142) is provided in the bonding apparatus D100-5 for supplying a bonding gas to the semiconductor wafer 202 during the bonding of the semiconductor chip 302. The in-situ gas flow ensures that the droplet condensation caused by the Joule-Thomson effect is minimized at the bonding interface. As such, by using the bonding apparatus D100-5 of the present disclosure for chip-on-wafer bonding, robust bonding yield can be achieved while tiny non-bond defects can be removed.

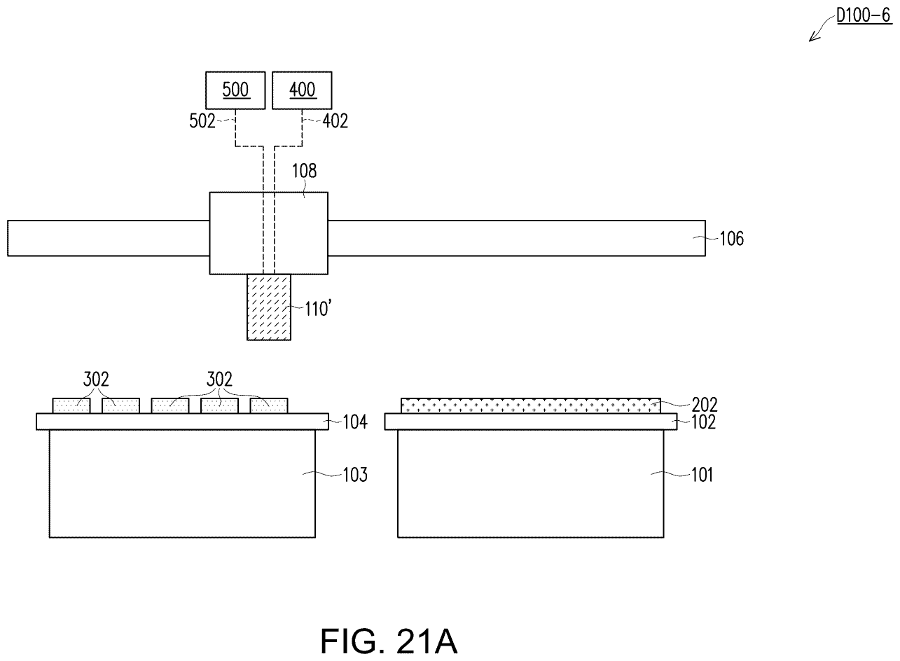

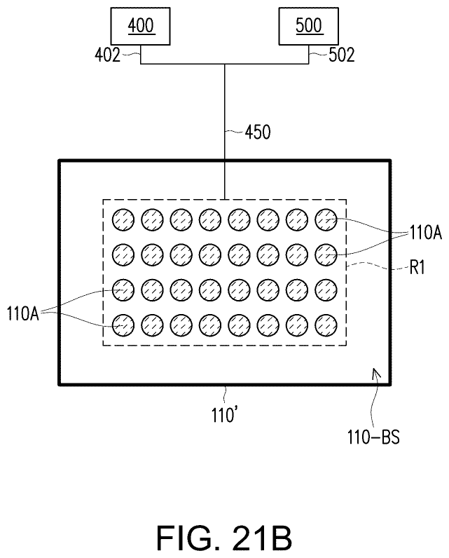

FIG. 21A to FIG. 24B are schematic sectional and bottom views of various stages in a method of bonding semiconductor chips using a bonding apparatus according to some other exemplary embodiments of the disclosure. The method illustrated in FIG. 21A to FIG. 24B is similar to the method illustrated in FIG. 1A to FIG. 6B. Therefore, the same reference numerals are used to refer to the same or liked parts, and its detailed description will be omitted herein. The difference between the embodiments is that a bond head 110′ of the bonding apparatus D100-6 shown in in FIG. 21A to FIG. 24B is used as the gas supplying mechanism.

As illustrated in FIG. 21A, in the exemplary embodiment, the bonding apparatus D100-6 is free of a gas flow chamber 120. Instead, the gas supplying system 500 is connected to the bond head 110′, wherein the gas supplying system 500 is configured to supply a bonding gas to the tube structures 110A of the bond head 110′. As illustrated from a bottom view of the bond head 110′ shown in FIG. 21B, the bond head 110′ includes the tube structures 110A located in a center region R1 on a bottom surface 110-BS of the bond head 110′. In some embodiments, the tube structures 110A are connected to the vacuum device 400 through the pipe structure 402 and the pipe structure 450, while the tube structures 110A are also connected to the gas supplying system 500 through the pipe structure 502 and the pipe structure 450. In some embodiments, the pipe structure 450 is shared between the vacuum device 400 and the gas supplying system 500 for supplying a vacuum or supplying a bonding gas to the tube structures 110A. Although one pipe structure 450 is illustrated herein, it is noted that there may be a plurality of pipe structures 450 that are connected to each of the tube structures 110A of the bond head 110′. Furthermore, in the exemplary embodiment, although a shared pipe structure 450 is used between the vacuum device 400 and the gas supplying system 500, it is noted that separated pipe structures may be used for supplying a vacuum from the vacuum device 400 to the tube structures 110A and for supplying a bonding gas from the gas supplying system 500 to the tube structures 110A. In other words, the arrangement of the pipe structures (402, 450, 502) are not particularly limited, and can be designed to fulfill different gas flow/vacuum suction requirements.

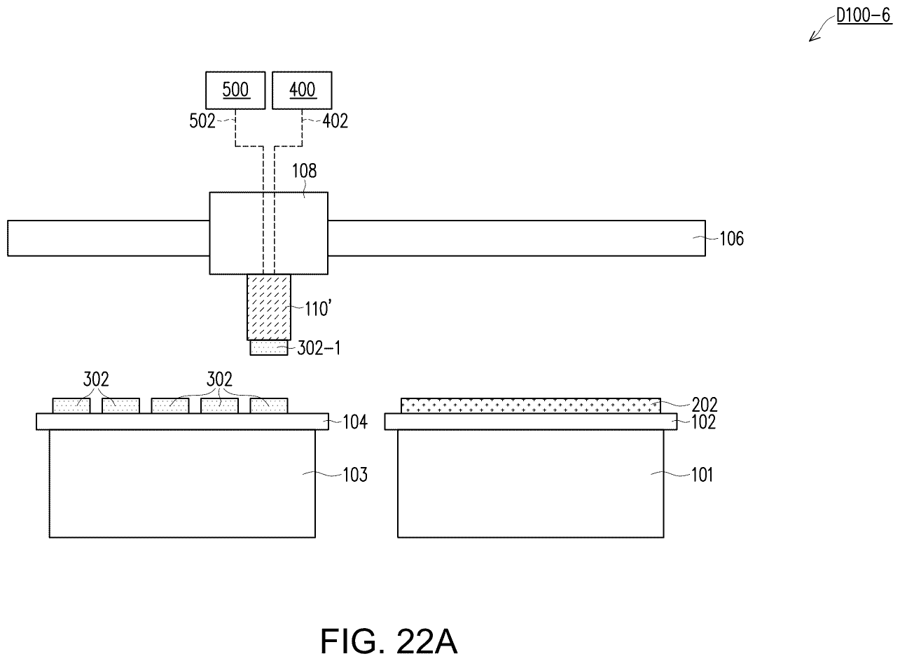

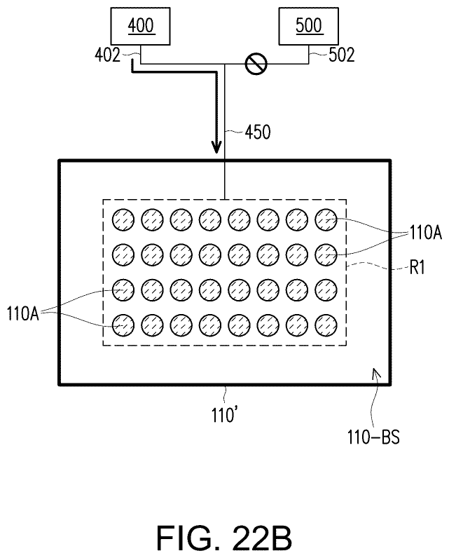

Referring to FIG. 22A and FIG. 22B, in the method of bonding semiconductor chips of the present disclosure, the bond head 110′ of the bonding apparatus D100-6 is driven to a position located over the support structure 104 to pick up the first semiconductor chip 302-1 from the support structure 104. For example, the vacuum device 400 supplies vacuum to each of the tube structures 110A through the pipe structure 402 and the pipe structure 450. As such, the tube structures 110A of the bond head 110′ can pick up the first semiconductor chip 302-1 through the vacuum suction force supplied by the vacuum device 400. During the supply of the vacuum by the vacuum device 400 to the tube structures 110A, the gas supplying system 500 may be turned off. In some embodiments, a valve (not shown) for controlling the gas flow from the pipe structure 502 to the pipe structure 450 is closed. As such, an outflow of the bonding gas from the gas supplying system 500 to the tube structures 110A during the picking process is prevented.

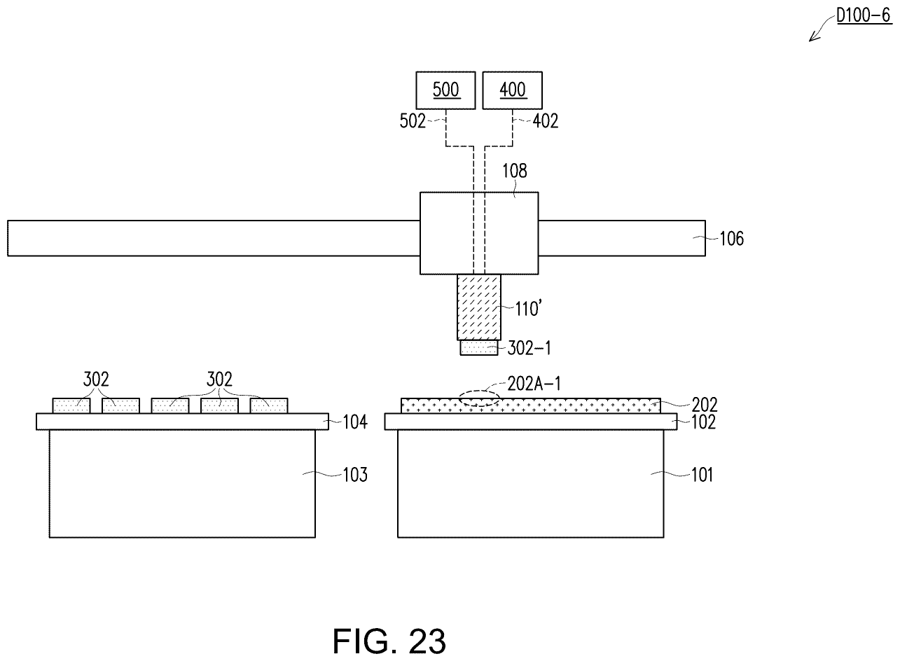

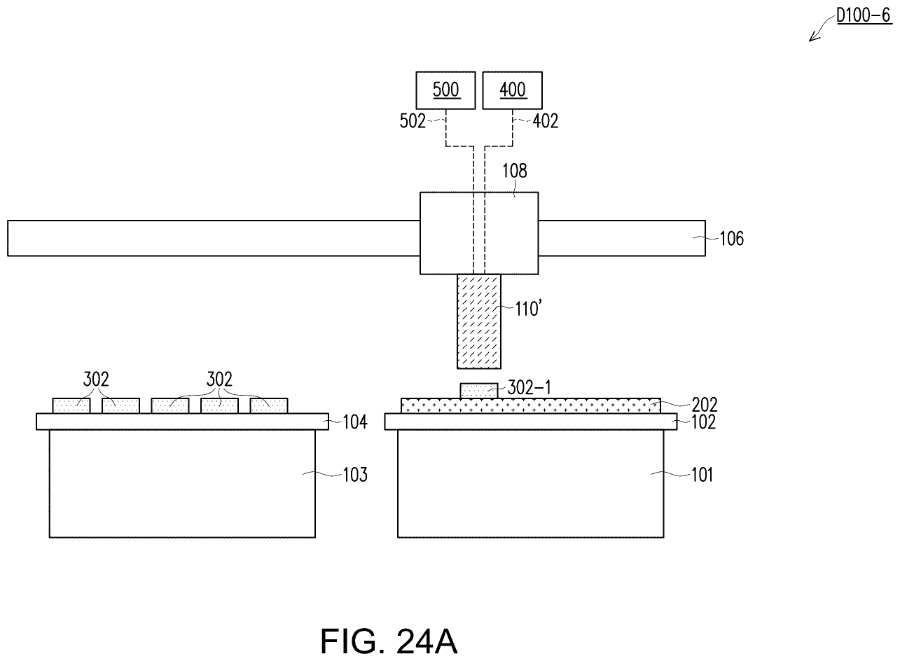

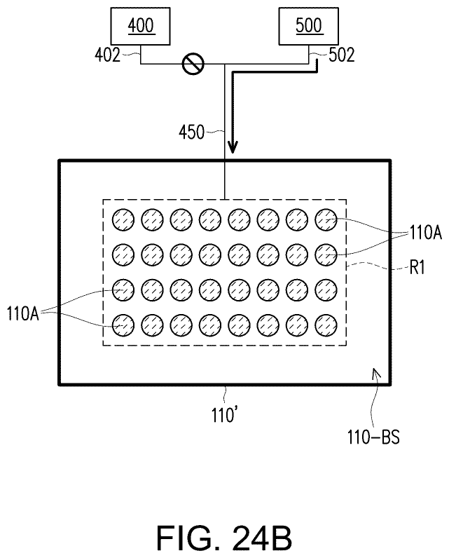

Referring to FIG. 23, in a subsequent step, after picking up the first semiconductor chip 302-1, the bond head 110′ is driven for moving the first semiconductor chip 302-1 to a position located over a first bonding region 202A-1 of the semiconductor wafer 202. Thereafter, referring to FIG. 24A to FIG. 24B, a bonding process may be performed for bonding the first semiconductor chip 302-1 to the first bonding region 202A-1 of the semiconductor wafer 202. During the bonding process, the vacuum supplied to the first semiconductor chip 302-1 from the bond head 110′ is turned off, while the gas supplying system 500 is turned on so that a bonding gas (e.g. helium) is supplied to the semiconductor wafer 202 during the bonding of the first semiconductor chip 302-1.

For example, referring to FIG. 24B, during the bonding process, the vacuum device 400 is turned off, and a valve (not shown) for controlling the vacuum from the pipe structure 402 to the pipe structure 450 is closed. As such, the first semiconductor chip 302-1 is released from the bond head 110′ for bonding, and the bonding gas may be supplied from the gas supplying system 500 to each of the tube structures 110A through the pipe structure 502 and the pipe structure 450. In certain embodiments, the bonding gas supplied to the tube structures 110A may flow through the bonding interface between the first semiconductor chip 302-1 and the semiconductor wafer 202 during the entire bonding process. Upon completion of the bonding of the first semiconductor chip 302-1 to the semiconductor wafer 202, the picking and placing process of another semiconductor chip 302 can be performed in a similar way.

In the embodiment shown in FIG. 21A to FIG. 24B, the tube structures 110A of the bond head 110′ is used as a gas supplying mechanism in the bonding apparatus D100-6 for supplying a bonding gas to the semiconductor wafer 202 during the bonding of the semiconductor chip 302. The in-situ gas flow ensures that the droplet condensation caused by the Joule-Thomson effect is minimized at the bonding interface. As such, by using the bonding apparatus D100-6 of the present disclosure for chip-on-wafer bonding, robust bonding yield can be achieved while tiny non-bond defects can be removed.

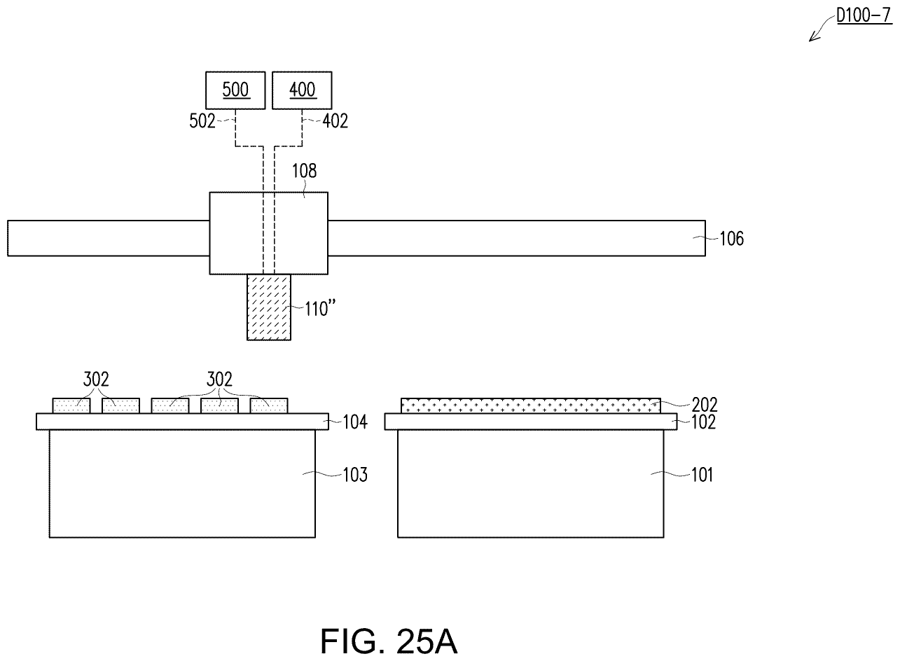

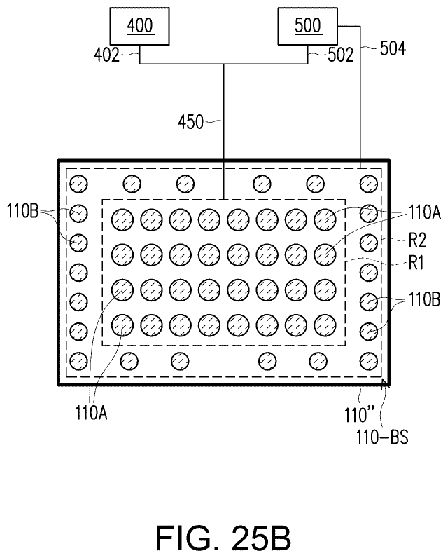

FIG. 25A to FIG. 27B are schematic sectional and bottom views of various stages in a method of bonding semiconductor chips using a bonding apparatus according to some other exemplary embodiments of the disclosure. The method illustrated in FIG. 25A to FIG. 27B is similar to the method illustrated in FIG. 21A to FIG. 24B. Therefore, the same reference numerals are used to refer to the same or liked parts, and its detailed description will be omitted herein. The difference between the embodiments is that the bond head 110′ is replaced with a bond head 110″ in the bonding apparatus D100-7 shown in FIG. 25A to FIG. 27B.

As illustrated in FIG. 25A and FIG. 25B, in the exemplary embodiment, the bond head 110″ includes the tube structures 110A located in a center region R1 on a bottom surface 110-BS of the bond head 110″. In some embodiments, the tube structures 110A are connected to the vacuum device 400 through the pipe structure 402 and the pipe structure 450, while the tube structures 110A are also connected to the gas supplying system 500 through the pipe structure 502 and the pipe structure 450. In some embodiments, the bond head 110″ further includes a plurality of apertures 110B located in a peripheral region R2 on the bottom surface 110-BS of the bond head 110″ and surrounding the plurality of tube structures 110A. The apertures 110B are a type of gas supplying mechanism used in the various bonding apparatus of the present disclosure. For example, the apertures 110B are connected to the gas supplying system 500 though one or more pipe structures 504. In some embodiments, the gas supplying system 500 is configured for supplying the bonding gas to the apertures 110B on the bond head 110″ through the pipe structures 504. In certain embodiments, the apertures 110B are disconnected from the vacuum device 400.

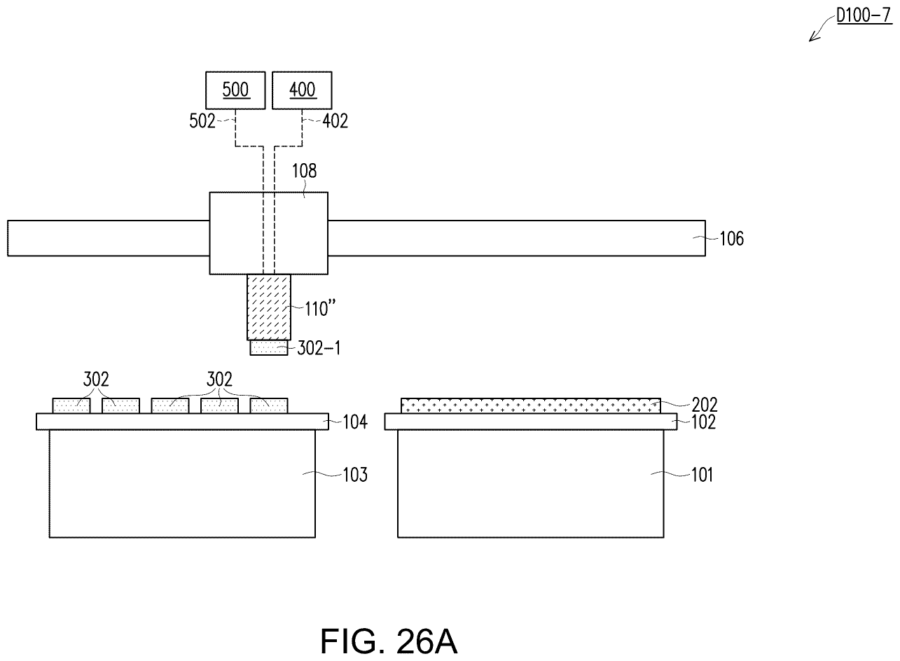

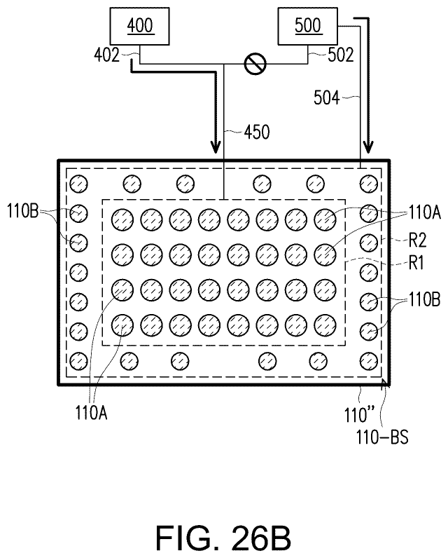

Referring to FIG. 26A and FIG. 26B, in the method of bonding semiconductor chips of the present disclosure, the bond head 110″ of the bonding apparatus D100-7 is driven to a position located over the support structure 104 to pick up the first semiconductor chip 302-1 from the support structure 104. For example, the vacuum device 400 supplies vacuum to each of the tube structures 110A through the pipe structure 402 and the pipe structure 450. As such, the tube structures 110A of the bond head 110″ can pick up the first semiconductor chip 302-1 through the vacuum suction force supplied by the vacuum device 400. During the supply of the vacuum by the vacuum device 400 to the tube structures 110A, a valve (not shown) for controlling the gas flow from the pipe structure 502 to the pipe structure 450 is closed. In some embodiments, the gas supplying system 500 may be turned on, so that a bonding gas (e.g. helium) is supplied to the apertures 110B on the bond head 110″. The flowing of the bonding gas to the tube structures 110A is blocked due to the closed valve blocking the gas flow path of the pipe structure 502. As such, in the exemplary embodiment, vacuum can be supplied to the tube structures 110A for picking up the first semiconductor chip 302-1, while bonding gas can be supplied to the apertures 110B to ensure preliminary flowing of the bonding gas to the bonding interface. In some alternative embodiments, the gas supplying system 500 is turned off during the picking process, and the bonding gas may be supplied to the bonding interface upon release/bonding of the first semiconductor chip 302-1.

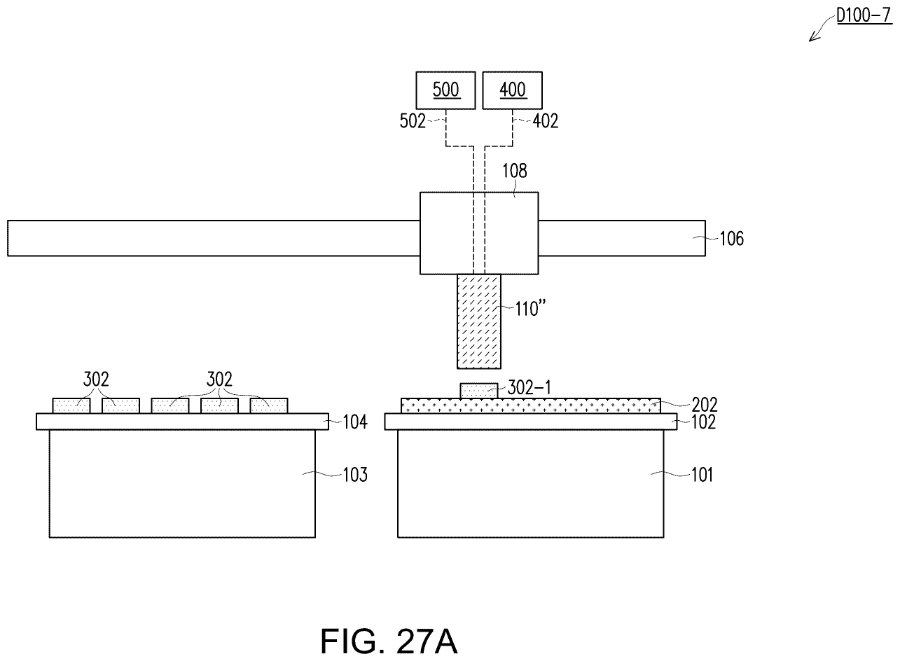

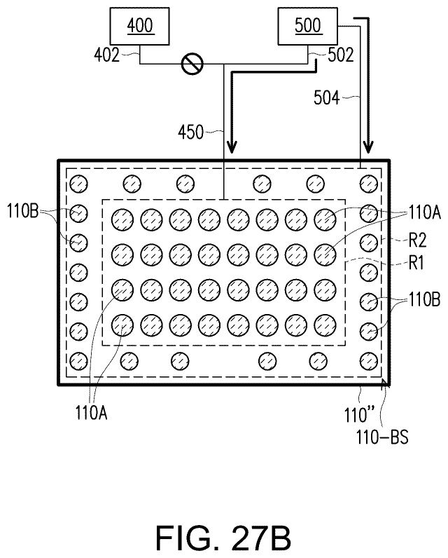

As illustrated in FIG. 27A and FIG. 27B, after picking up the first semiconductor chip 302-1, the bond head 110″ is driven for moving the first semiconductor chip 302-1 to a position located over a first bonding region 202A-1 of the semiconductor wafer 202. Thereafter, a bonding process may be performed for bonding the first semiconductor chip 302-1 to the first bonding region 202A-1 of the semiconductor wafer 202. During the bonding process, the vacuum device 400 is turned off, and a valve (not shown) for controlling the vacuum from the pipe structure 402 to the pipe structure 450 is closed. As such, the first semiconductor chip 302-1 is released from the bond head 110″, and the bonding gas may be supplied from the gas supplying system 500 to each of the tube structures 110A through the pipe structure 502 and the pipe structure 450, and further supplied to the apertures 110B through the pipe structure 504. In certain embodiments, the bonding gas supplied to the tube structures 110A and the apertures 110B may flow through the bonding interface between the first semiconductor chip 302-1 and the semiconductor wafer 202 during the entire bonding process. Upon completion of the bonding of the first semiconductor chip 302-1 to the semiconductor wafer 202, the picking and placing process of another semiconductor chip 302 can be performed in a similar way.

In the embodiment shown in FIG. 25A to FIG. 27B, the tube structures 110A and the apertures 110B on the bond head 110″ are used as a gas supplying mechanism in the bonding apparatus D100-7 for supplying a bonding gas to the semiconductor wafer 202 during the bonding of the semiconductor chip 302. The in-situ gas flow ensures that the droplet condensation caused by the Joule-Thomson effect is minimized at the bonding interface. As such, by using the bonding apparatus D100-7 of the present disclosure for chip-on-wafer bonding, robust bonding yield can be achieved while tiny non-bond defects can be removed.

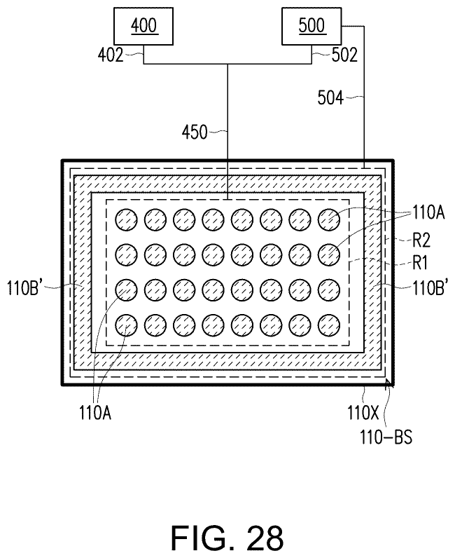

FIG. 28 is a schematic bottom view of a bond head in a bonding apparatus according to some other exemplary embodiments of the disclosure. The bond head 110X illustrated in FIG. 28 is similar to the bond head 110″ described in FIG. 25B. Therefore, the same reference numerals are used to refer to the same or liked parts and its detailed description is omitted herein. The difference between the embodiments, is that the apertures 110B shown in FIG. 25B are replaced with a gas flow channel 110B′.

Referring to FIG. 28, the gas flow channel 110B′ is located on the bond head 110X and encircling the plurality of tube structures 110A. In some embodiments, the gas flow channel 110B′ is connected to the gas supplying system 500 through the pipe structures 504, and wherein the gas flow channel 110B′ is disconnected from the vacuum device 400. In the exemplary embodiment, the gas flow channel 110B′ functions in a similar manner to the apertures 110B described in FIG. 25A to FIG. 27B for suppling bonding gas. As such, the method of operating the bond head 110X can be referred to the method of operating the bond head 110″ described in FIG. 25A to FIG. 27B, thus will not be repeated herein.

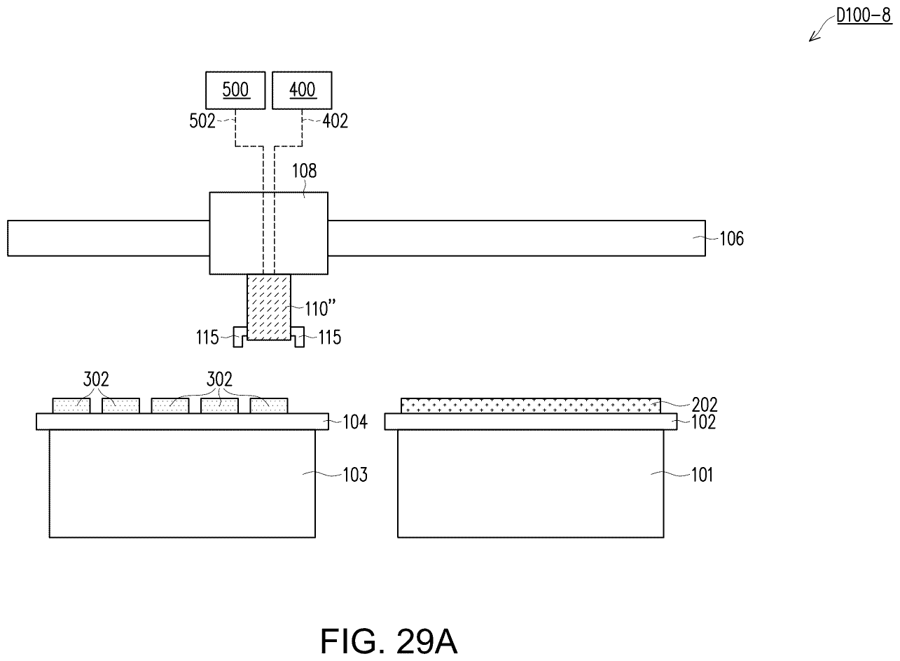

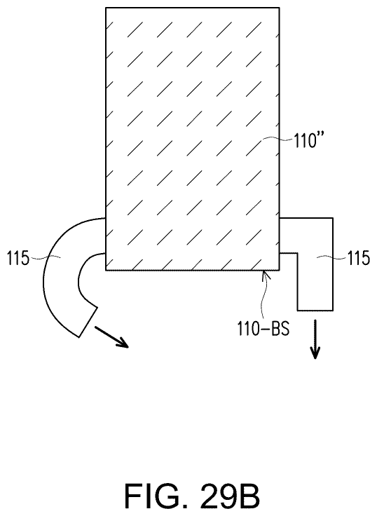

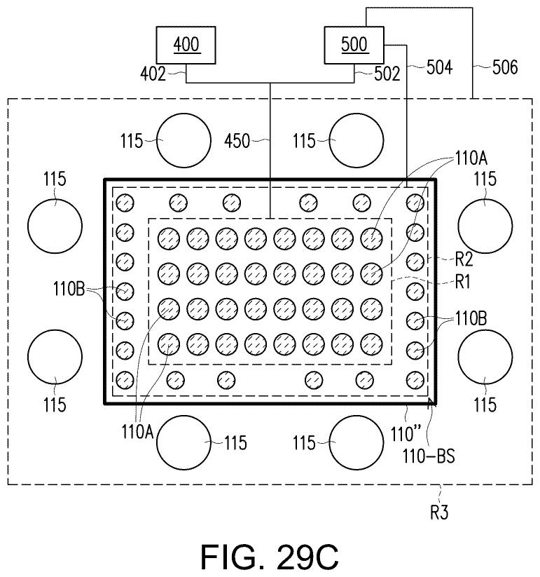

FIG. 29A to FIG. 31B are schematic sectional and bottom views of various stages in a method of bonding semiconductor chips using a bonding apparatus according to some other exemplary embodiments of the disclosure. The method illustrated in FIG. 29A to FIG. 31B is similar to the method illustrated in FIG. 25A to FIG. 27B. Therefore, the same reference numerals are used to refer to the same or liked parts, and its detailed description will be omitted herein. The difference between the embodiments is that a plurality of gas flow arms 115 is further provided in the bonding apparatus D100-8 shown in FIG. 29A to FIG. 31B.

As illustrated in FIG. 29A to FIG. 29C, in the exemplary embodiment, a plurality of gas flow arms 115 is attached on side surfaces of the bond head 110″. The gas flow arms 115 are a type of gas supplying mechanism used in the various bonding apparatus of the present disclosure. In some embodiments, the gas flow arms 115 are connected to the gas supplying system 500 through one or more pipe structures 506. For example, the pipe structures 506 may pass through the bond head 110″ to reach the gas flow arms 115. In some embodiments, the gas flow arms 115 are located in a third region R3 surrounding the peripheral region R2 of the bond head 110″. In some embodiments, the gas supplying system 500 is configured for supplying the bonding gas to the gas flow arms 115 on the bond head 110″ through the pipe structures 506. In certain embodiments, the gas flow arms 115 are disconnected from the vacuum device 400. From an enlarge view of the bond head 110″ shown in FIG. 29B, it is noted that the gas flow arms 115 attached on side surfaces of the bond head 110″ may have different arrangements. For example, in the illustrated embodiment, the gas flow arms 115 are made of a flexible material, whereby an angle of bonding gas flowing out of the gas flow arms 115 may be different, and the angle can be appropriately adjusted based on requirement. Furthermore, although six gas flow arms 115 are illustrated herein, it is noted that the number of gas flow arms 115 is not particularly limited, and can be adjusted based on product requirement.

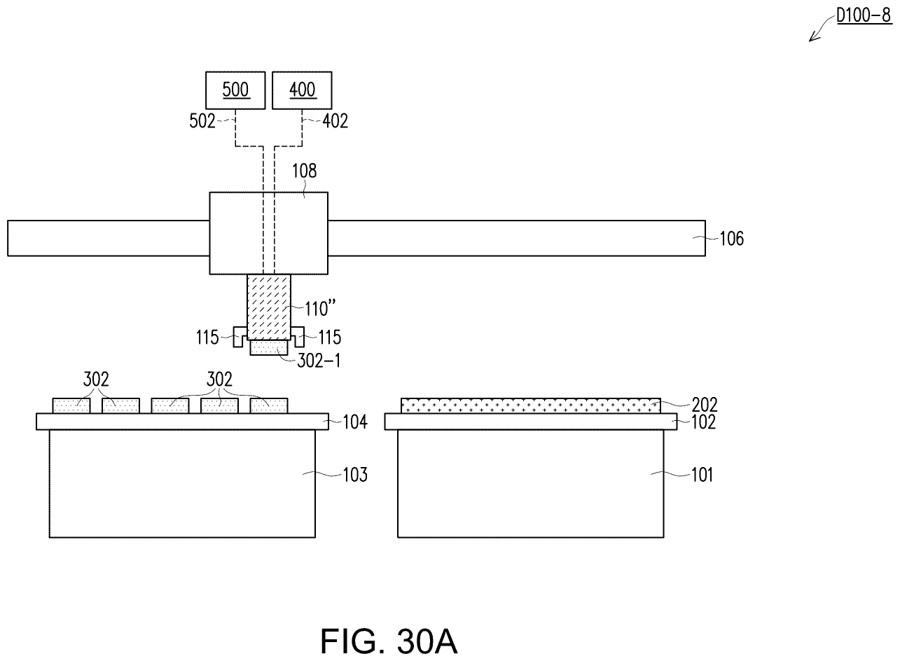

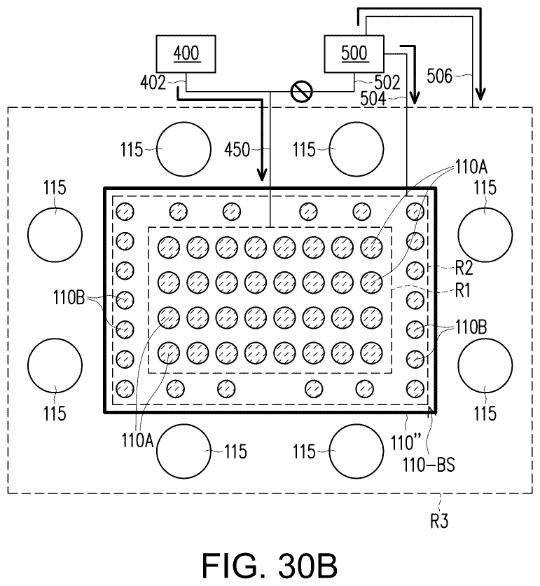

Referring to FIG. 30A to FIG. 30B, in the method of bonding semiconductor chips of the present disclosure, the bond head 110″ of the bonding apparatus D100-8 is driven to a position located over the support structure 104 to pick up the first semiconductor chip 302-1 from the support structure 104. For example, the vacuum device 400 supplies vacuum to each of the tube structures 110A through the pipe structure 402 and the pipe structure 450. As such, the tube structures 110A of the bond head 110″ can pick up the first semiconductor chip 302-1 through the vacuum suction force supplied by the vacuum device 400. During the supply of the vacuum by the vacuum device 400 to the tube structures 110A, a valve (not shown) for controlling the gas flow from the pipe structure 502 to the pipe structure 450 is closed. In some embodiments, the gas supplying system 500 may be turned on, so that a bonding gas (e.g. helium) is supplied to the apertures 110B on the bond head 110″, and further supplied to the gas flow arms 115. The flowing of the bonding gas to the tube structures 110A is blocked due to the closed valve blocking the gas flow path of the pipe structure 502. As such, in the exemplary embodiment, vacuum can be supplied to the tube structures 110A for picking up the first semiconductor chip 302-1, while bonding gas can be supplied to the apertures 110B and the gas flow arms 115 to ensure preliminary flowing of the bonding gas to the bonding interface.

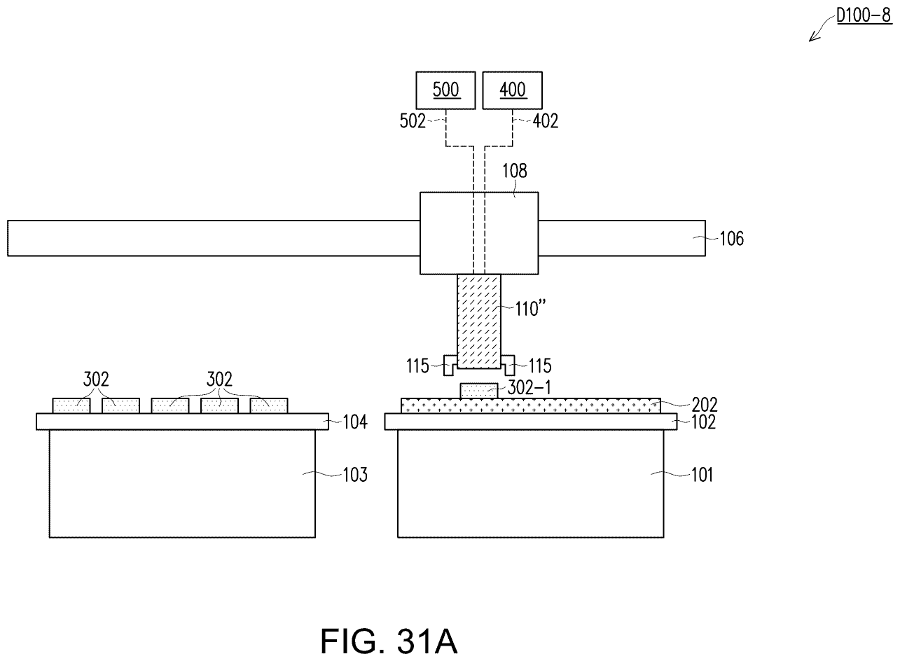

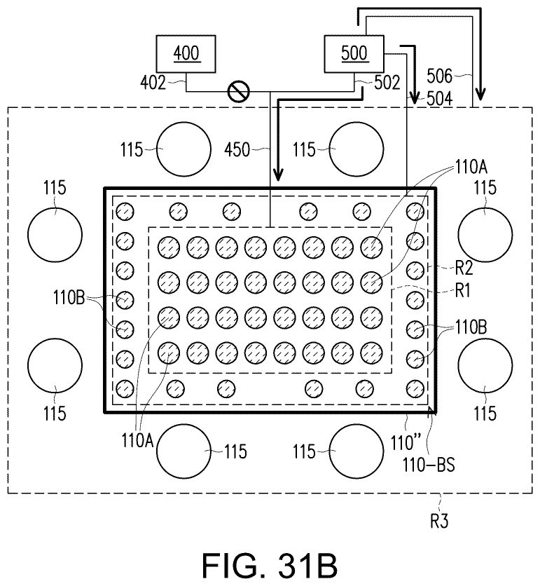

As illustrated in FIG. 31A and FIG. 31B, after picking up the first semiconductor chip 302-1, the bond head 110″ is driven for moving the first semiconductor chip 302-1 to a position located over a first bonding region 202A-1 of the semiconductor wafer 202. Thereafter, a bonding process may be performed for bonding the first semiconductor chip 302-1 to the first bonding region 202A-1 of the semiconductor wafer 202. During the bonding process, the vacuum device 400 is turned off, and a valve (not shown) for controlling the vacuum from the pipe structure 402 to the pipe structure 450 is closed. As such, the first semiconductor chip 302-1 is released from the bond head 110″, and the bonding gas may be supplied from the gas supplying system 500 to each of the tube structures 110A through the pipe structure 502 and the pipe structure 450, and further supplied to the apertures 110B through the pipe structure 504, and further supplied to the gas flow arms 115 through the pipe structure 506. In the exemplary embodiment, the bonding gas is simultaneously supplied to the bonding interface through the tube structures 110A, the apertures 110B and the gas flow arms 115, however the disclosure is not limited thereto. In some alternative embodiments, the bonding gas is supplied to the bonding interface through any one of the tube structures 110A, the apertures 110B and the gas flow arms 115, while the other two gas flowing paths may be blocked or removed. In other words, any one of the tube structures 110A, the apertures 110B and the gas flow arms 115 are used as a main gas supplying mechanism for supplying bonding gas, while the other two gas flowing paths are used as back-up gas supplying mechanisms for optionally supplying bonding gas.

In the exemplary embodiment, the bonding gas supplied to the tube structures 110A, the apertures 110B and the gas flow arms 115 may flow through the bonding interface between the first semiconductor chip 302-1 and the semiconductor wafer 202 during the entire bonding process. Upon completion of the bonding of the first semiconductor chip 302-1 to the semiconductor wafer 202, the picking and placing process of another semiconductor chip 302 can be performed in a similar way.

In the embodiment shown in FIG. 29A to FIG. 31B, the tube structures 110A, the apertures 110B and the gas flow arms 115 on the bond head 110″ are used as a gas supplying mechanism in the bonding apparatus D100-8 for supplying a bonding gas to the semiconductor wafer 202 during the bonding of the semiconductor chip 302. The in-situ gas flow ensures that the droplet condensation caused by the Joule-Thomson effect is minimized at the bonding interface. As such, by using the bonding apparatus D100-8 of the present disclosure for chip-on-wafer bonding, robust bonding yield can be achieved while tiny non-bond defects can be removed.

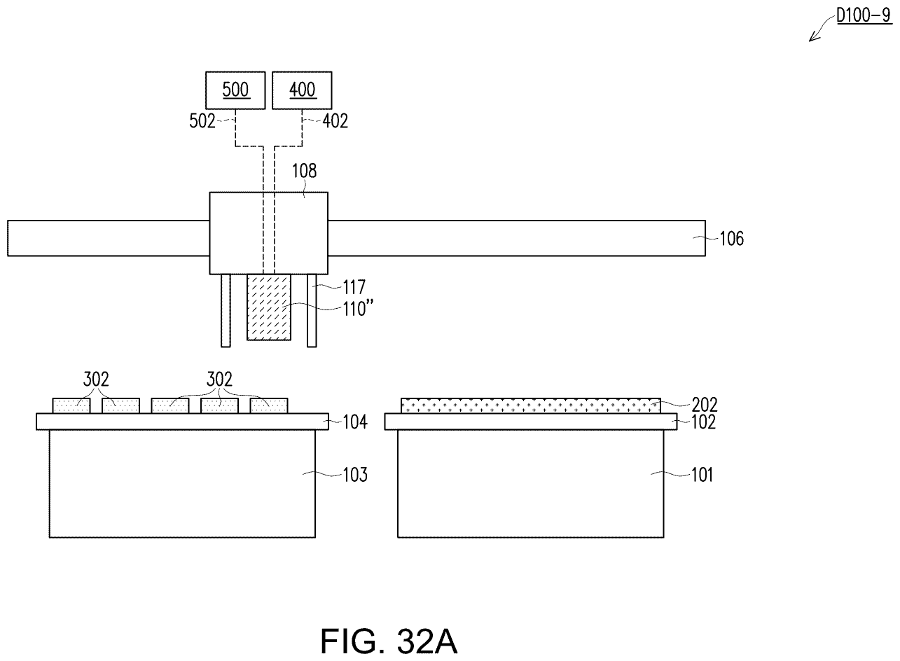

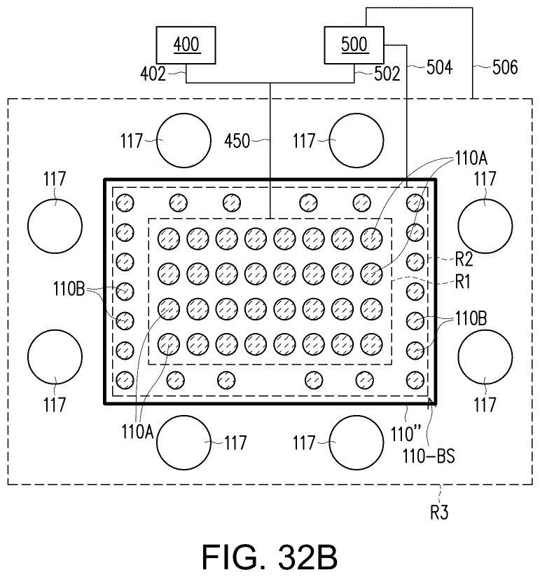

FIG. 32A and FIG. 32B are schematic sectional and bottom views of a bonding apparatus according to some other exemplary embodiments of the disclosure. The bonding apparatus D100-9 illustrated in FIG. 32A and FIG. 32B is similar to the bonding apparatus D100-8 illustrated in FIG. 29A to FIG. 29C. Therefore, the same reference numerals are used to refer to the same or liked parts and its detailed description is omitted herein. The difference between the embodiments, is that the gas flow arms 115 shown in FIG. 29A to FIG. 29C are replaced with the gas flow arms 117 shown in FIG. 32A and FIG. 32B.

In the embodiment shown in FIG. 29A to FIG. 29C, the gas flow arms 115 are located on side surfaces of the bond head 110″. However, the disclosure is not limited thereto. For example, in the embodiment shown in FIG. 32A and FIG. 32B, the gas flow arms 117 are located on the guide piece 108. In the exemplary embodiment, the gas flow arms 117 functions in a similar manner to the gas flow arms 115 described in FIG. 29A to FIG. 31B for suppling bonding gas. As such, the method of operating the gas flow arms 117 can be referred to the method of operating the gas flow arms 115 described in FIG. 29A to FIG. 31B, thus will not be repeated herein.

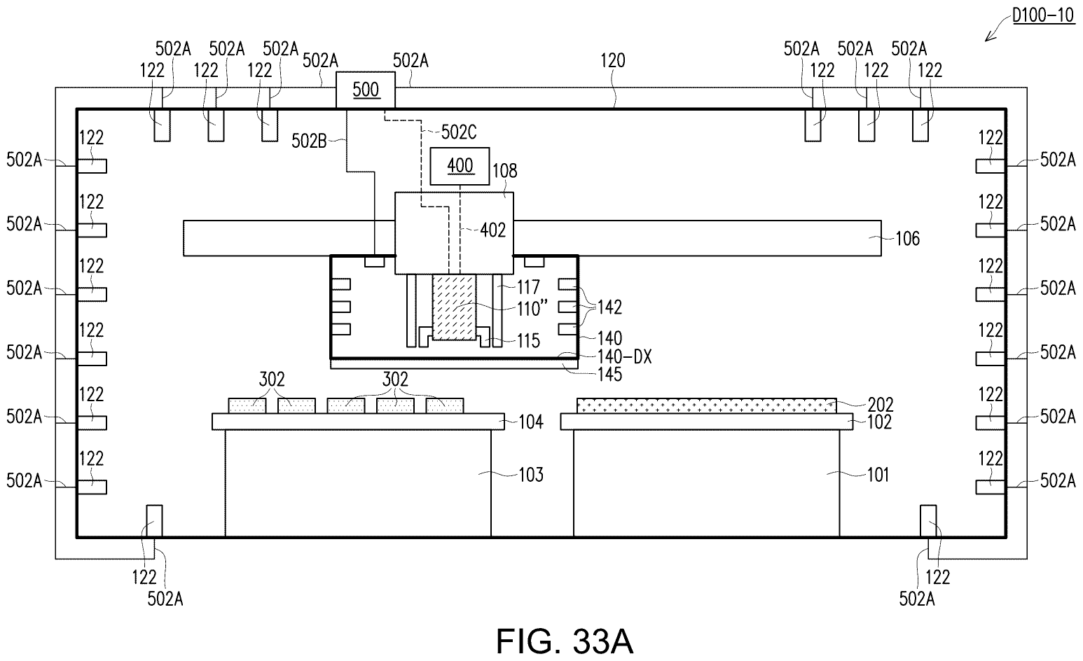

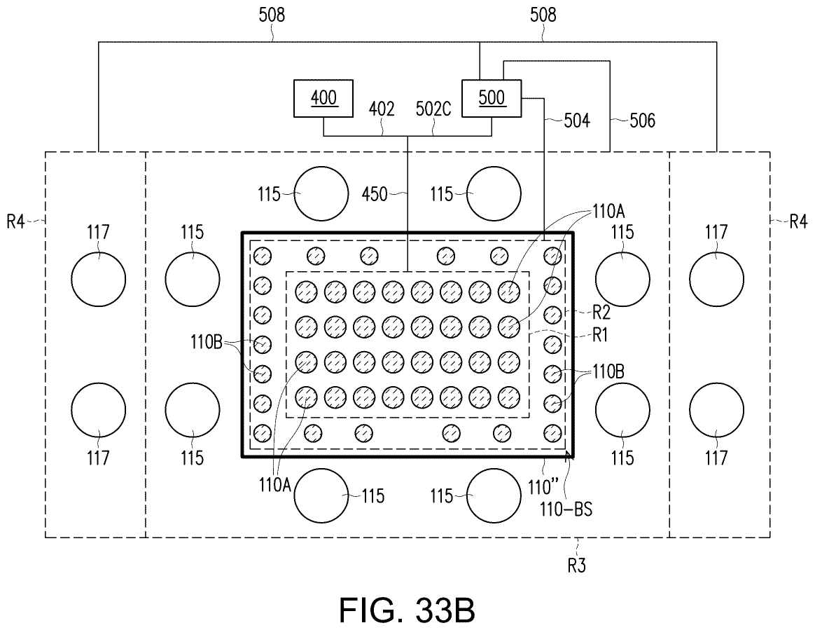

FIG. 33A to FIG. 36 are schematic sectional and bottom views of various stages in a method of bonding semiconductor chips using a bonding apparatus according to some other exemplary embodiments of the disclosure. The structure and method illustrated in FIG. 33A to FIG. 36 are similar to any one of the structures and methods illustrated in FIG. 1A to FIG. 6B, FIG. 19 to FIG. 20, FIG. 29A to FIG. 31B and FIG. 32A to FIG. 32B. Therefore, the same reference numerals are used to refer to the same or liked parts and its detailed description is omitted herein.

As illustrated in FIG. 33A to FIG. 33B, the bonding apparatus D100-10 includes various gas supplying mechanisms including gas supplying tubes 122, gas supplying tubes 142, tube structures 110A, apertures 110B, gas flow arms 115 and gas flow arms 117. In the exemplary embodiment, the bonding gas can be supplied to each of the above gas supplying mechanisms (122, 142, 110A, 110B, 115, 117) through various pipe structures. The arrangement of the pipe structures is not particularly limited, and FIG. 33A to FIG. 33B illustrate one way of connecting the gas supplying mechanisms (122, 142, 110A, 110B, 115, 117) to the gas supplying system 500.

In the exemplary embodiment, the gas supplying system 500 is connected to the gas supplying tubes 122 through the pipe structures 502A, and is connected to the gas supplying tubes 142 through the pipe structures 502B. Furthermore, the gas supplying system 500 is connected to tube structures 110A of the bond head 110″ through the pipe structures 502C, and is connected to the apertures 110B located in a peripheral region R2 of the bond head 110″ through the pipe strictures 504. Moreover, the gas supplying system 500 is connected to the gas flow arms 115 in the third region R3 through the pipe structures 506, and is connected to the gas flow arms 117 in the fourth region R4 through the pipe structures 508.

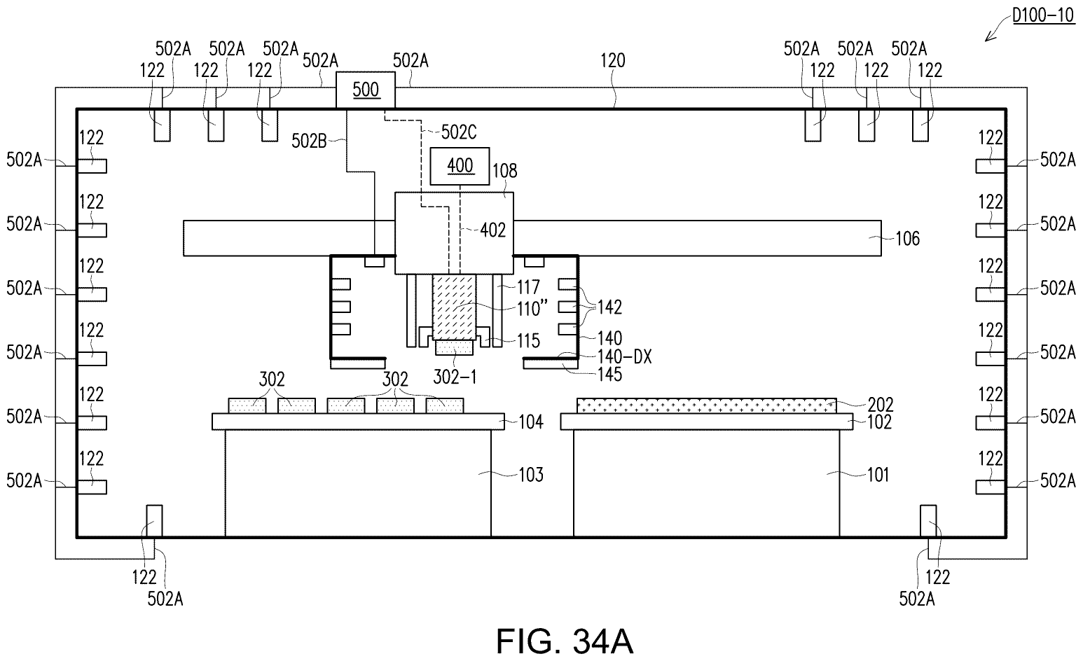

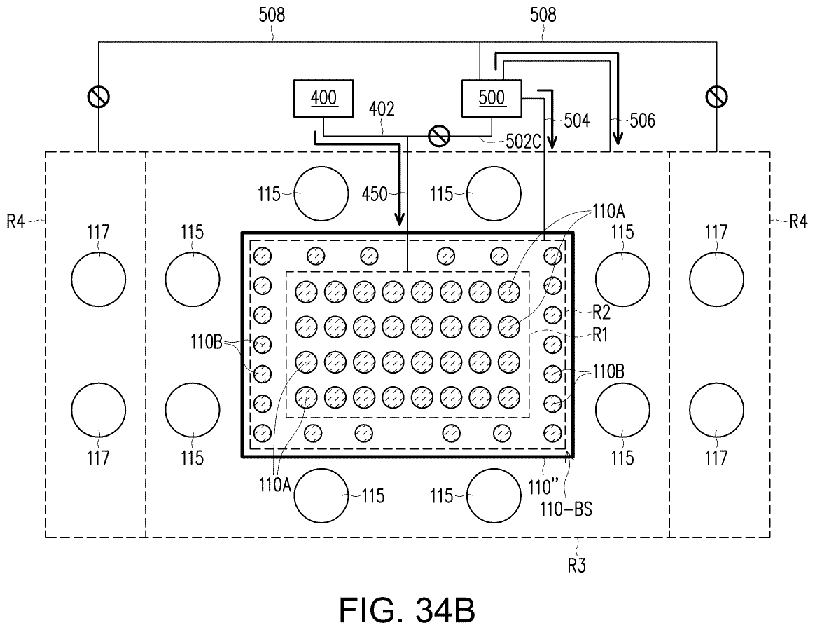

Referring to FIG. 34A to FIG. 34B, in the method of bonding semiconductor chips of the present disclosure, the bond head 110″ of the bonding apparatus D100-10 is driven to a position located over the support structure 104 to pick up the first semiconductor chip 302-1 from the support structure 104. For example, the vacuum device 400 supplies vacuum to each of the tube structures 110A through the pipe structure 402 and the pipe structure 450.

As such, the tube structures 110A of the bond head 110″ can pick up the first semiconductor chip 302-1 through the vacuum suction force supplied by the vacuum device 400.

During the supply of the vacuum by the vacuum device 400 to the tube structures 110A, a valve (not shown) for controlling the gas flow from the pipe structure 502C to the pipe structure 450 is closed, and valves (not shown) for controlling the gas flow from the pipe structure 508 to the gas flow arms 117 are closed. In some embodiments, the gas supplying system 500 may be turned on, so that a bonding gas (e.g. helium) is supplied to the gas supplying tubes 122, supplied to the gas supplying tubes 142, supplied to the apertures 110B on the bond head 110″, and further supplied to the gas flow arms 115. The flowing of the bonding gas to the tube structures 110A and the gas flow arms 117 are blocked due to the closed valves blocking the gas flow path of the pipe structures 502C and 508. In the exemplary embodiment, the gas flow arms 117 are back-up gas supplying mechanisms that can be optionally turned on or turned off based on requirements. As such, in the illustrated embodiment, vacuum can be supplied to the tube structures 110A for picking up the first semiconductor chip 302-1, while bonding gas can be supplied to the gas supplying tubes 122, 142, the apertures 110B and the gas flow arms 115 to ensure preliminary flowing of the bonding gas to the bonding interface.

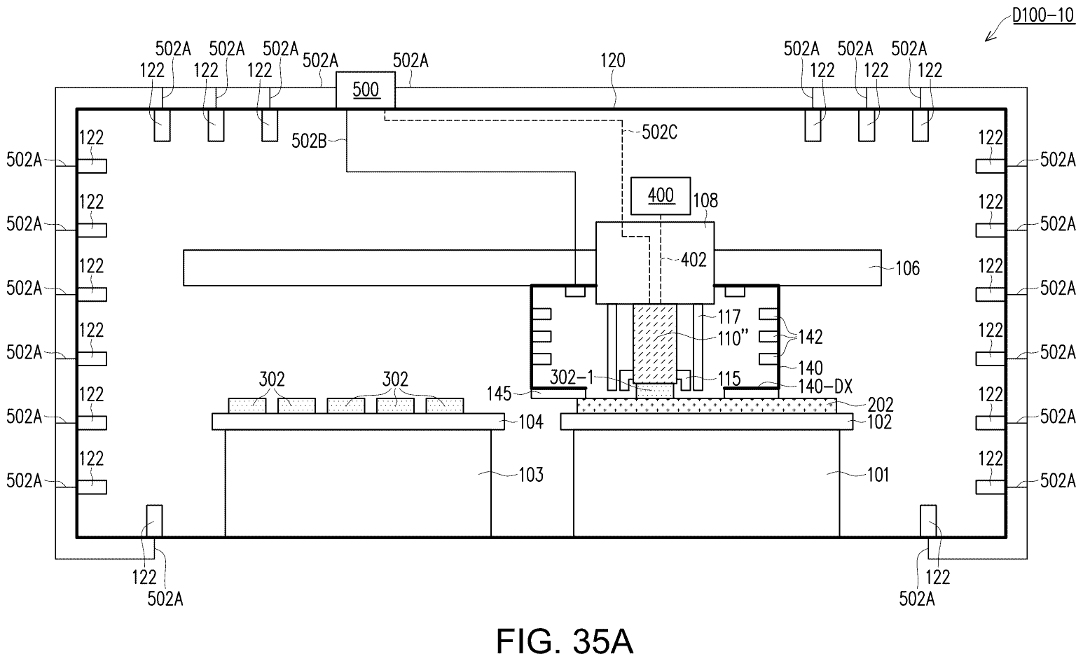

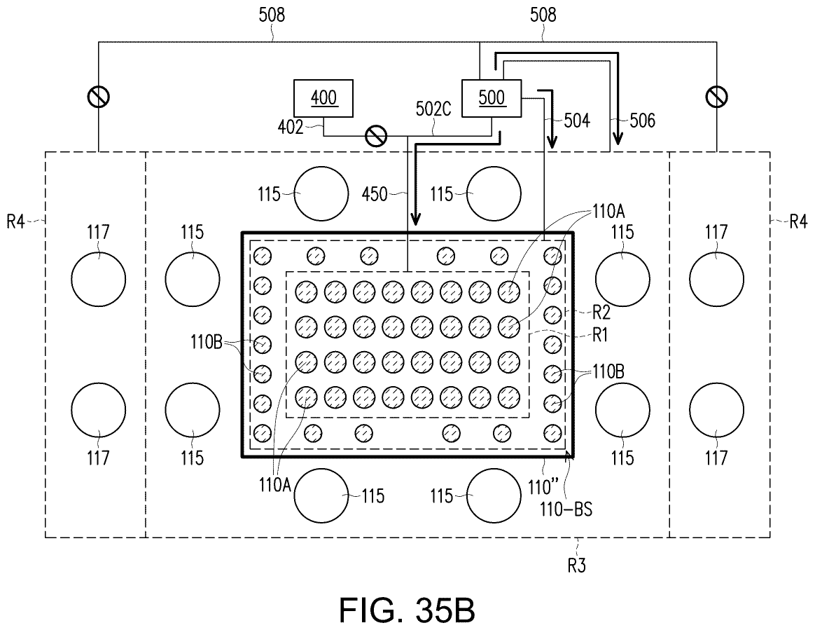

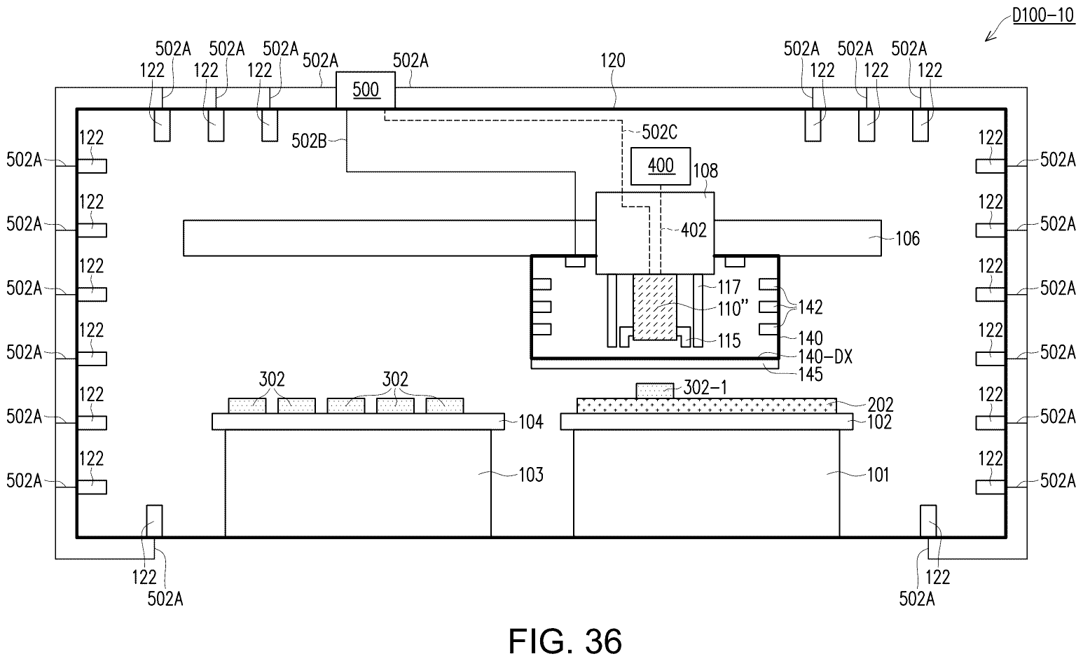

As illustrated in FIG. 35A and FIG. 35B, after picking up the first semiconductor chip 302-1, the bond head 110″ is driven for moving the first semiconductor chip 302-1 to a position located over a first bonding region 202A-1 of the semiconductor wafer 202. Thereafter, a bonding process may be performed for bonding the first semiconductor chip 302-1 to the first bonding region 202A-1 of the semiconductor wafer 202. During the bonding process, the vacuum device 400 is turned off, and a valve (not shown) for controlling the vacuum from the pipe structure 402 to the pipe structure 450 is closed. As such, the first semiconductor chip 302-1 is released from the bond head 110″, and the bonding gas may be supplied from the gas supplying system 500 to the gas supplying tubes 122, 142, supplied to each of the tube structures 110A through the pipe structure 502 and the pipe structure 450, and further supplied to the apertures 110B through the pipe structure 504, and further supplied to the gas flow arms 115 through the pipe structure 506. In the exemplary embodiment, the bonding gas supplied to the gas supplying tubes 122, 142, the tube structures 110A, the apertures 110B and the gas flow arms 115 may flow through the bonding interface between the first semiconductor chip 302-1 and the semiconductor wafer 202 during the entire bonding process. Referring to FIG. 36, upon completion of the bonding of the first semiconductor chip 302-1 to the semiconductor wafer 202, the bond head 110″ is retracted back into the cover structure 140, and the movable door 140-DX is closed. Thereafter, the picking and placing process of another semiconductor chip 302 can be performed in a similar way.

In the embodiment shown in FIG. 33A to FIG. 36, various gas supplying mechanisms (122, 142, 110A, 110B, 115, 117) are provided in the bonding apparatus D100-10 for supplying a bonding gas to the semiconductor wafer 202 during the bonding of the semiconductor chip 302. The in-situ gas flow ensures that the droplet condensation caused by the Joule-Thomson effect is minimized at the bonding interface. As such, by using the bonding apparatus D100-10 of the present disclosure for chip-on-wafer bonding, robust bonding yield can be achieved while tiny non-bond defects can be removed.

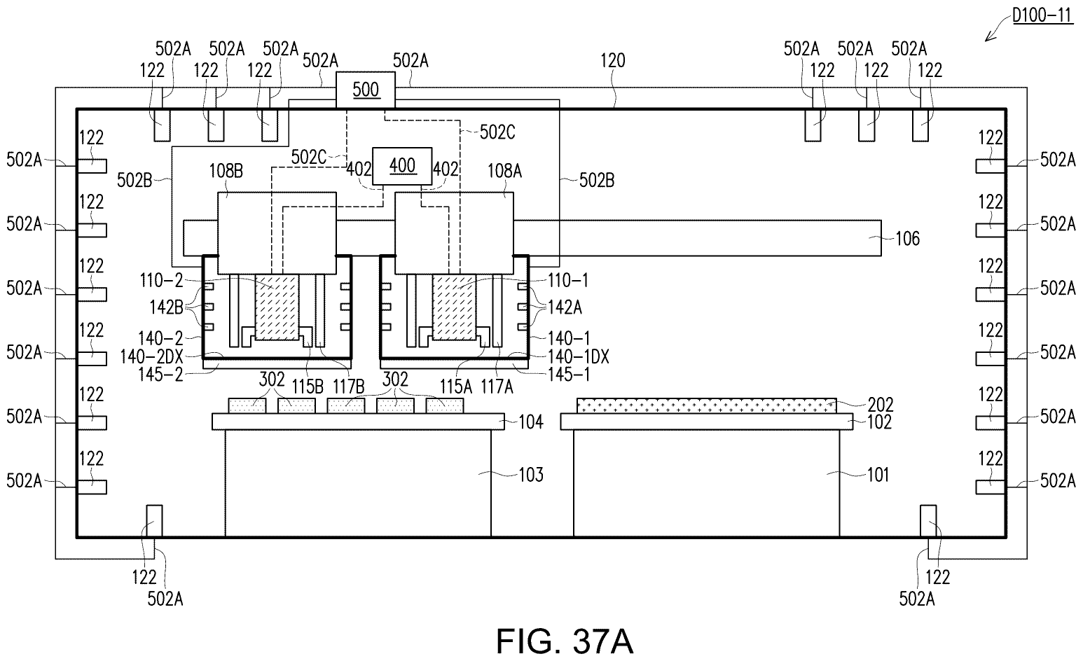

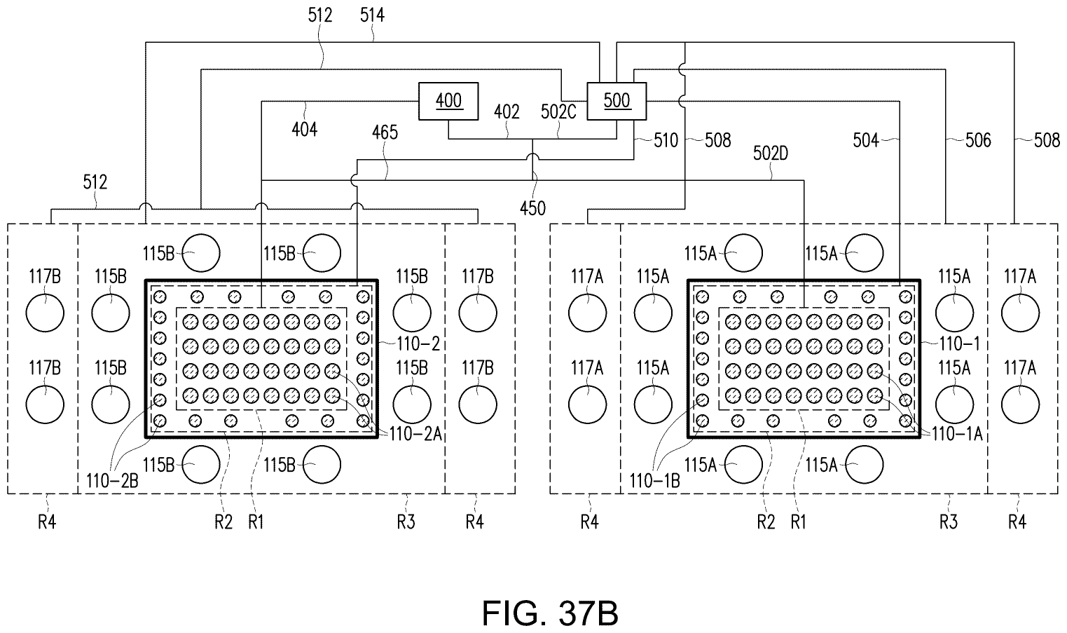

FIG. 37A to FIG. 40B are schematic sectional and bottom views of various stages in a method of bonding semiconductor chips using a bonding apparatus according to some other exemplary embodiments of the disclosure. The structure and method illustrated in FIG. 37A to FIG. 40B are similar to the structure and method illustrated in FIG. 37A to FIG. 40B. Therefore, the same reference numerals are used to refer to the same or liked parts and its detailed description is omitted herein. The difference between the embodiments is that two bond heads (110-1, 110-2) are used in FIG. 37A to FIG. 40B instead of a single bond head 110″.

In the exemplary embodiment, the guide piece 108A, 108B, the bond head 110-1, 110-2, the tube structures 110-1A, 110-2A, the apertures 110-1B, 110-2B, the gas flow arms 115A, 115B, the gas flow arms 117A, 117B, the cover structures 140-1, 140-2, the movable doors 140-1DX, 140-2DX, the gas supplying tubes 142A, 142B and the protection layer 145-1, 145-2 functions in a similar manner to the guide piece 108, the bond head 110″, the tube structures 110A, the apertures 110B, the gas flow arms 115, the gas flow arms 117, the cover structures 140, the movable doors 140-DX, the gas supplying tubes 142 and the protection layer 145 described in the previous embodiments. As such, their method of operation will not be repeated herein, and the detailed method and function can be referred to the previous embodiments.

In the exemplary embodiment, the gas supplying system 500 is connected to the gas supplying tubes 122 through the pipe structures 502A, and is connected to the gas supplying tubes 142A, 142B through the pipe structures 502B. Furthermore, the gas supplying system 500 is connected to tube structures 110-1A, 110-2A of the bond heads 110-1, 110-2 through the pipe structures 502C, 450, 502D. The gas supplying system 500 is connected to the apertures 110-1B, 110-2B located in a peripheral regions R2 of the bond heads 110-1, 110-2 through the pipe strictures 504, 510. Moreover, the gas supplying system 500 is connected to the gas flow arms 115A, 115B in the third regions R3 through the pipe structures 506, 514 and is connected to the gas flow arms 117A, 117B in the fourth regions R4 through the pipe structures 508, 512. Furthermore, the vacuum device 400 supplies vacuum to each of the tube structures 110-1A, 110-1B through the pipe structure 402, 404, 450, 465, 502D.

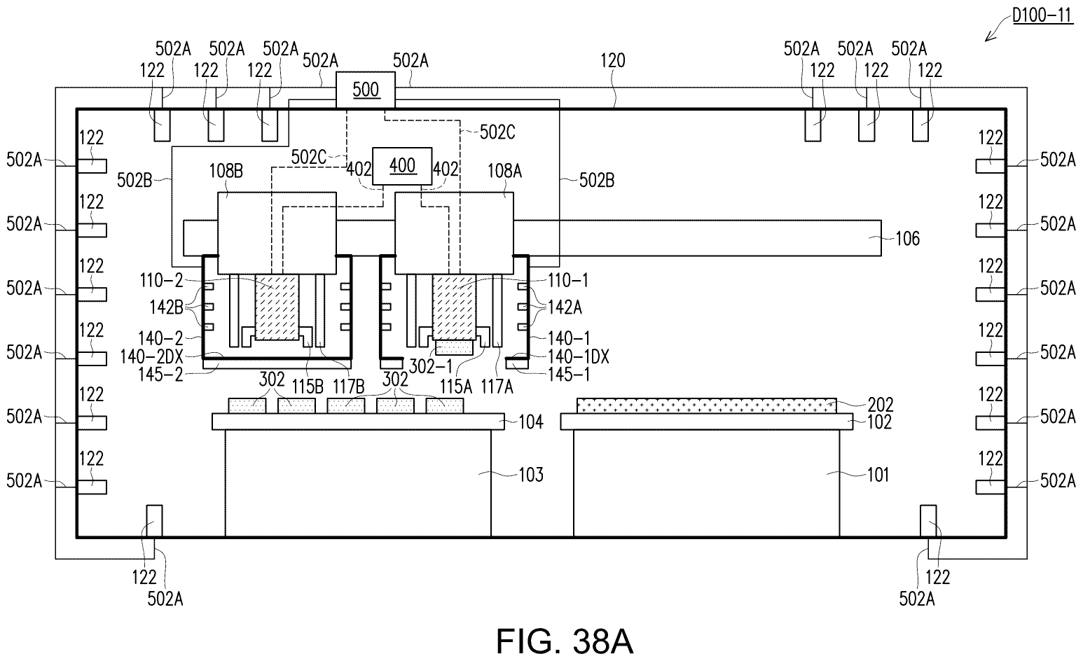

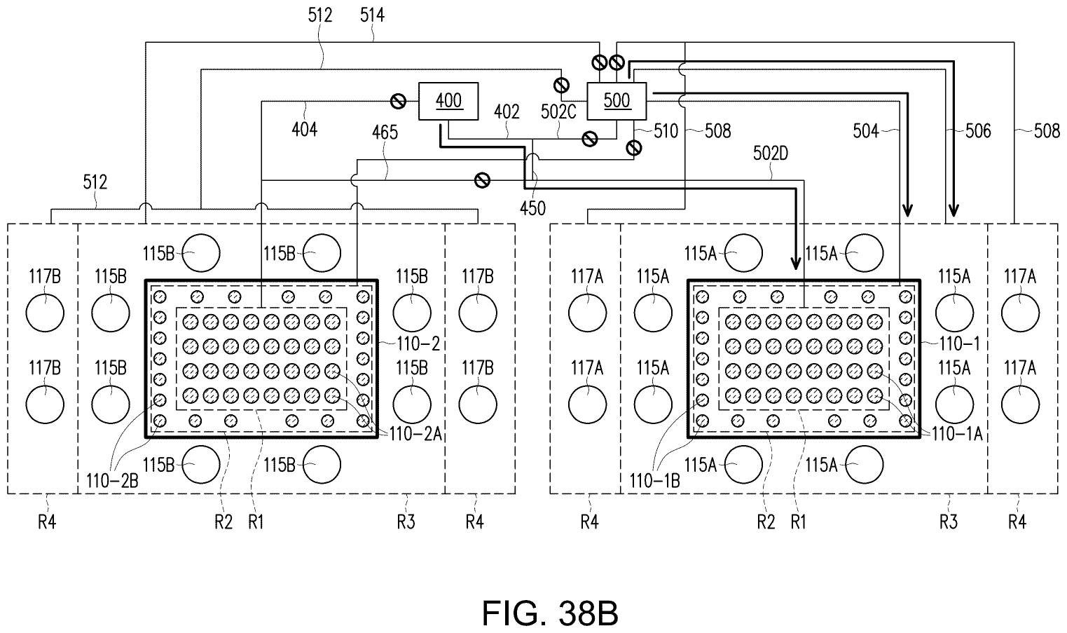

Referring to FIG. 38A to FIG. 38B, in the method of bonding semiconductor chips of the present disclosure, the bond head 110-1 (first bond head) of the bonding apparatus D100-11 is driven to a position located over the support structure 104 to pick up the first semiconductor chip 302-1 from the support structure 104. For example, the vacuum device 400 supplies vacuum to each of the tube structures 110-1A through the pipe structures 402, 450, 502D. As such, the tube structures 110-1A of the bond head 110-1 can pick up the first semiconductor chip 302-1 through the vacuum suction force supplied by the vacuum device 400. At this stage, valves (not shown) for controlling the vacuum from the vacuum device to the pipe structures 404, 465 are closed, so that no vacuum is supplied to the bond head 110-2 (second bond head).

During the supply of the vacuum by the vacuum device 400 to the tube structures 110-1A of the bond head 110-1, valves (not shown) for controlling the gas flow from the gas supplying system 500 to the pipe structures 502C, 508, 510, 512, 514 are closed. In certain embodiments, the gas supplying system 500 may be turned on, so that a bonding gas (e.g. helium) is supplied to the gas supplying tubes 122, supplied to the gas supplying tubes 142A, supplied to the apertures 110-1B on the bond head 110-1, and further supplied to the gas flow arms 115A. The flowing of the bonding gas to the tube structures 110-1A and the gas flow arms 117A are blocked due to the closed valves blocking the gas flow path of the pipe structures 502C and 508. In the exemplary embodiment, the gas flow arms 117A are back-up gas supplying mechanisms that can be optionally turned on or turned off based on bonding requirements. As such, in the illustrated embodiment, vacuum can be supplied to the tube structures 110-1A for picking up the first semiconductor chip 302-1, while bonding gas can be supplied to the gas supplying tubes 122, 142A, the apertures 110-1B and the gas flow arms 115A to ensure preliminary flowing of the bonding gas to the bonding interface.

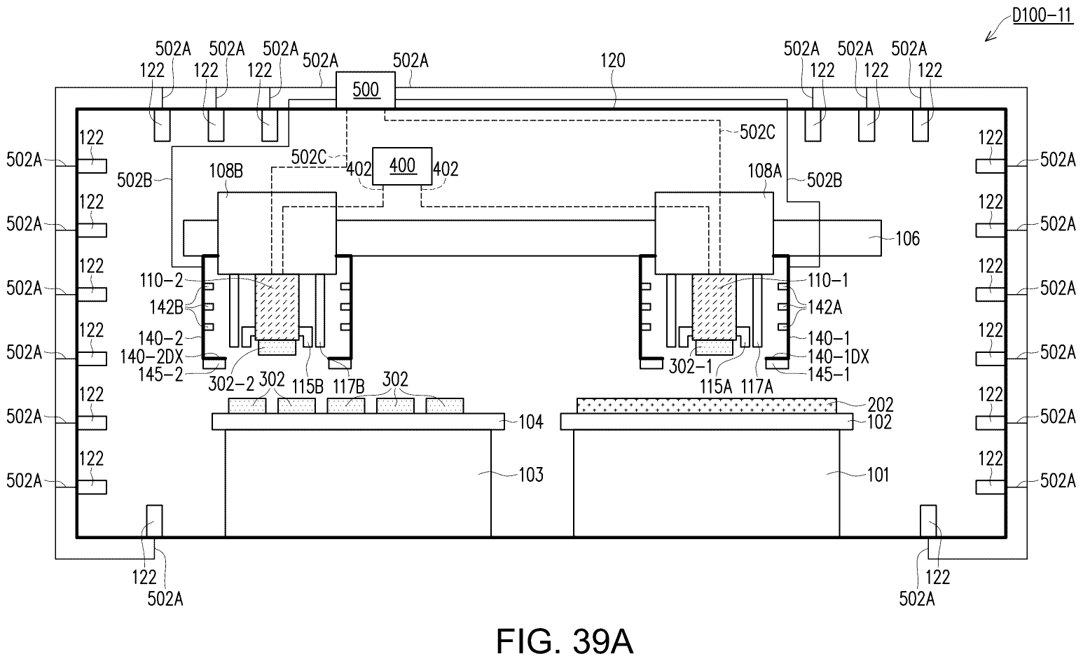

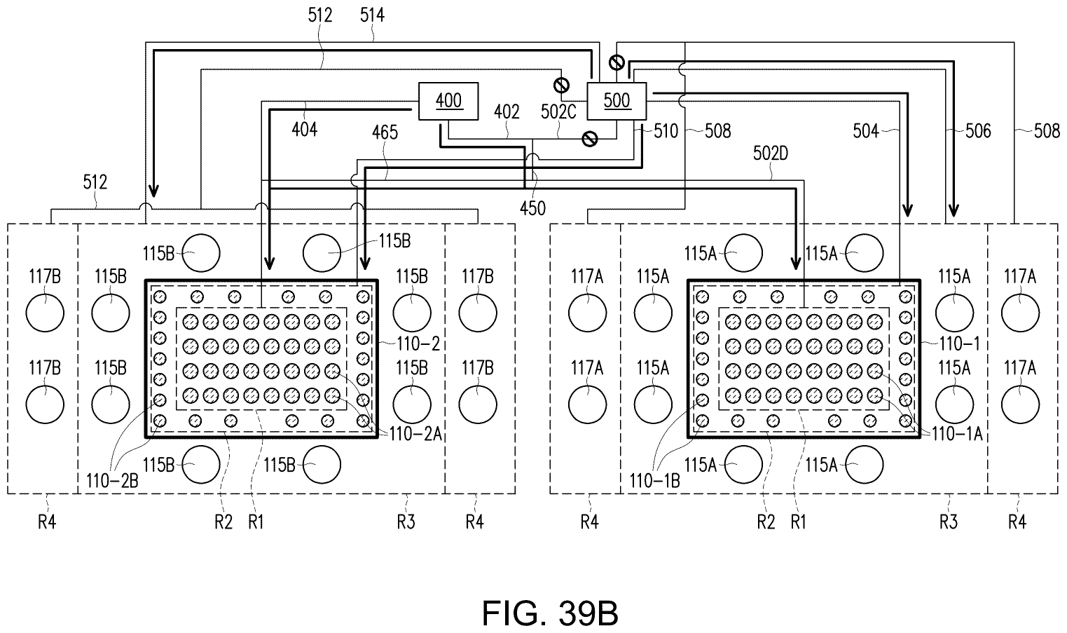

Referring to FIG. 39A to FIG. 39B, in a subsequent step, after picking up the first semiconductor chip 302-1, the bond head 110-1 is driven for moving the first semiconductor chip 302-1 to a position located over a first bonding region 202A-1 of the semiconductor wafer 202. Simultaneously, the bond head 110-2 (second bond head) of the bonding apparatus D100-11 may be driven to a position located over the support structure 104 to pick up a second semiconductor chip 302-2 from the support structure 104. For example, the vacuum device 400 supplies vacuum to each of the tube structures 110-2A through the pipe structures 402, 404, 450, 465. As such, the tube structures 110-2A of the bond head 110-2 can pick up the second semiconductor chip 302-2 through the vacuum suction force supplied by the vacuum device 400.

During the supply of the vacuum by the vacuum device 400 to the tube structures 110-1A, 110-2A of the bond heads 110-1, 110-2, valves (not shown) for controlling the gas flow from the gas supplying system 500 to the pipe structures 502C, 508, 512 are closed. In certain embodiments, the gas supplying system 500 may be turned on, so that a bonding gas (e.g. helium) is supplied to the gas supplying tubes 122, supplied to the gas supplying tubes 142A, 142B, supplied to the apertures 110-1B, 110-2B on the bond heads 110-1, 110-2, and further supplied to the gas flow arms 115A, 115B. As such, in the illustrated embodiment, vacuum can be supplied to the both of the tube structures 110-1A, 110-2A for picking up the first semiconductor chip 302-1 and the second semiconductor chip 302-2, while bonding gas can be supplied to the gas supplying tubes 122, 142A, 142B, the apertures 110-1B, 110-2B and the gas flow arms 115A, 115B to ensure preliminary flowing of the bonding gas to the bonding interface.

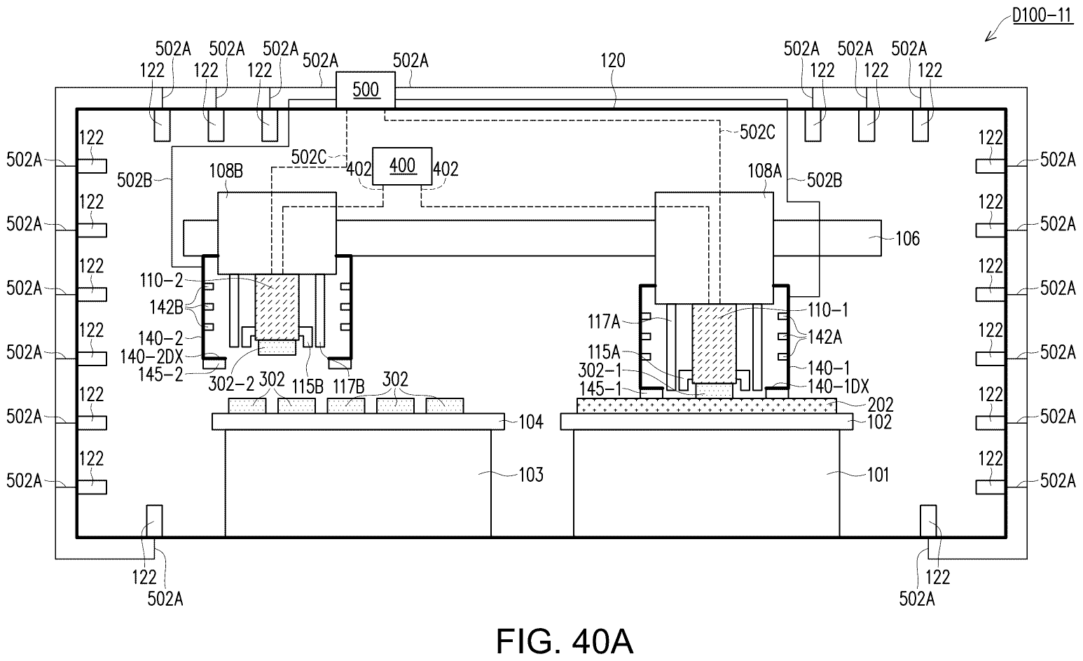

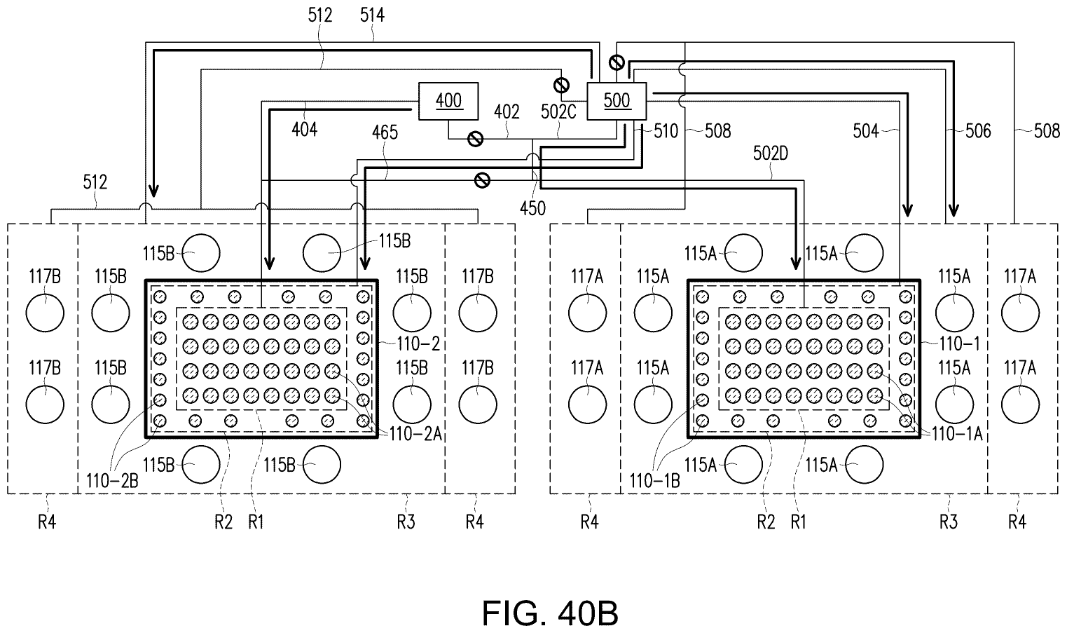

Referring to FIG. 40A and FIG. 40B, in a subsequent step, a bonding process may be performed for bonding the first semiconductor chip 302-1 to the first bonding region 202A-1 of the semiconductor wafer 202. During the bonding process, a valve (not shown) for controlling the vacuum from the pipe structure 402 to the pipe structure 450 is closed. For example, vacuum is still supplied from the vacuum device 400 to the tube structures 110-2A through the pipe structures 404, while vacuum supplied to the tube structures 110-1A is blocked due to the closed valve. As such, the first semiconductor chip 302-1 is released from the bond head 110-1, while the bond head 110-2 is still holding the second semiconductor chip 302-2.

In the exemplary embodiment, bonding gas is supplied from the gas supplying system 500 to the gas supplying tubes 122, 142A, 142B, supplied to each of the tube structures 110-1A through the pipe structures 502C, 450, 502D, and further supplied to the apertures 110-1B, 110-2B through the pipe structures 504, 510, and further supplied to the gas flow arms 115A through the pipe structure 506, 514. As such, the supplied bonding gas can flow through the bonding interface between the first semiconductor chip 302-1 and the semiconductor wafer 202 during the entire bonding process, and preliminary flowing of the bonding gas to the bonding interface of the second semiconductor chip 302-2 is ensured. Upon completion of the bonding of the first semiconductor chip 302-1 to the semiconductor wafer 202, the bonding of the second semiconductor chip 302-2 to the semiconductor wafer 202 may be achieved in a similar manner using the bond head 110-2. Thereafter, the picking and placing process of another semiconductor chip 302 can be performed in a similar way using the bond head 110-1.

In the embodiment shown in 37A to FIG. 40B, various gas supplying mechanisms (122, 142A, 142B, 110-1A, 110-2A, 110-1B, 110-2B, 115A, 115B, 117A, 117B) are provided in the bonding apparatus D100-11 for supplying a bonding gas to the semiconductor wafer 202 during the bonding of the semiconductor chip 302. The in-situ gas flow ensures that the droplet condensation caused by the Joule-Thomson effect is minimized at the bonding interface. As such, by using the bonding apparatus D100-11 of the present disclosure for chip-on-wafer bonding, robust bonding yield can be achieved while tiny non-bond defects can be removed.

In the above embodiments, although the bonding apparatus is illustrated for performing a chip-on-wafer (CoW) bonding process, the disclosure is not limited thereto. For example, in other embodiments, the illustrated bonding apparatus is applied for performing a wafer-on-wafer bonding process, or for performing the bonding between any two surfaces of semiconductor chips, dies, wafers, substrates, etc.

According to the above embodiments, in a method of bonding semiconductor chips of the present disclosure, various gas supplying mechanisms are provided in the bonding apparatus for supplying a bonding gas to the bonding interface between the semiconductor wafer and the semiconductor chip. The in-situ gas flow ensures that the droplet condensation caused by the Joule-Thomson effect is minimized at the bonding interface. As such, by using any one of the bonding apparatus of the present disclosure for chip-on-wafer bonding, robust bonding yield can be achieved while tiny non-bond defects can be removed.

In accordance with some embodiments of the present disclosure, a bonding apparatus includes a chuck table, a gantry frame, a bond head and a gas supplying mechanism. The chuck table is configured to support a semiconductor wafer. The gantry frame is disposed over the chuck table. The bond head is movably installed on the gantry frame, wherein the bond head is configured to pick up a semiconductor chip from a support structure, and for moving the semiconductor chip towards the chuck table for bonding to the semiconductor wafer. The gas supplying mechanism is configured to supply a bonding gas to the semiconductor wafer during the bonding of the semiconductor chip.

In accordance with some other embodiments of the present disclosure, a bonding apparatus includes a chuck table, a support structure, a bond head, a vacuum device and a gas supplying system. The chuck table is configured to support a semiconductor wafer. The support structure is configured to support a plurality of semiconductor chips. The bond head is configured to pick up a semiconductor chip from the support structure, and for bonding the semiconductor chip to the semiconductor wafer on the chuck table. The vacuum device is e connected to the bond head and configured for supplying a vacuum to the bond head. The gas supplying system is connected to the bond head and configured for supplying a bonding gas to the bond head.

In accordance with yet another embodiment of the present disclosure, a method of bonding semiconductor chips is described. The method includes the following steps. A semiconductor wafer is placed on a chuck table of a bonding apparatus. A bond head of the bonding apparatus is driven for picking up a first semiconductor chip from a support. The bond head is driven for moving the first semiconductor chip to a position located over a first bonding region of the semiconductor wafer. The first semiconductor chip is bonded to the first bonding region of the semiconductor wafer. A bonding gas is supplied to the semiconductor wafer through a gas supplying mechanism during the bonding of the first semiconductor chip to the semiconductor wafer.

The foregoing outlines features of several embodiments so that those skilled in the art may better understand the aspects of the disclosure. Those skilled in the art should appreciate that they may readily use the disclosure as a basis for designing or modifying other processes and structures for carrying out the same purposes and/or achieving the same advantages of the embodiments introduced herein. Those skilled in the art should also realize that such equivalent constructions do not depart from the spirit and scope of the disclosure, and that they may make various changes, substitutions, and alterations herein without departing from the spirit and scope of the disclosure.

What is claimed is:

1. A bonding apparatus, comprising:
a chuck table configured to support a semiconductor wafer;
a gantry frame disposed over the chuck table;
a bond head movably installed on the gantry frame, wherein the bond head is configured to pick up a semiconductor chip from a support structure, and for moving the semiconductor chip towards the chuck table for bonding to the semiconductor wafer; and
a gas supplying mechanism configured to supply a bonding gas to the semiconductor wafer during the bonding of the semiconductor chip.

2. The bonding apparatus according to claim 1, wherein the bonding apparatus further comprises a gas flow chamber, and the chuck table, the gantry frame, the bond head and the gas supplying mechanism are all located in the gas flow chamber.

3. The bonding apparatus according to claim 2, wherein the gas supplying mechanism comprises a plurality of first gas supplying tubes, and the plurality of first gas supplying tubes is located on inner surfaces of the gas flow chamber.

4. The bonding apparatus according to claim 1, wherein the bonding apparatus further comprises a cover structure, and the bond head is located within a space enclosed by the cover structure, the cover structure comprises a movable door, and wherein the movable door is configured to be opened and closed allowing the driving of the bond head outside the space of the cover structure when picking up the semiconductor chip from the support structure, and during the bonding of the semiconductor chip to the semiconductor wafer.

5. The bonding apparatus according to claim 4, wherein the gas supplying mechanism further comprises a plurality of second gas supplying tubes, and the plurality of second gas supplying tubes is located on inner surfaces of the cover structure.

6. The bonding apparatus according to claim 1, wherein the bond head comprises a plurality of tube structures, and wherein the bonding apparatus further comprises:
a vacuum device connected to the bond head configured for supplying a vacuum to the plurality of tube structures; and
a gas supplying system connected to the bond head configured for supplying the bonding gas to the plurality of tube structures, and
wherein the plurality of tube structures is configured to pick up the semiconductor chip through the vacuum supplied by the vacuum device, and
wherein the plurality of tube structures is configured to supply the bonding gas to the semiconductor wafer during the bonding of the semiconductor chip to the semiconductor wafer.

7. The bonding apparatus according to claim 6, wherein the gas supplying mechanism further comprises a plurality of apertures located on the bond head and surrounding the plurality of tube structures, and the plurality of apertures is configured to supply the bonding gas to the semiconductor wafer during the bonding of the semiconductor chip to the semiconductor wafer.

8. The bonding apparatus according to claim 1, wherein the gas supplying mechanism comprises a plurality of gas flow arms attached on side surfaces of the bond head, and the plurality of gas flow arms is configured to supply the bonding gas to the semiconductor wafer during the bonding of the semiconductor chip to the semiconductor wafer.

9. A bonding apparatus, comprising:
a chuck table configured to support a semiconductor wafer;
a support structure configured to support a plurality of semiconductor chips;
a bond head configured to pick up a semiconductor chip from the support structure, and for bonding the semiconductor chip to the semiconductor wafer on the chuck table;
a vacuum device connected to the bond head and configured for supplying a vacuum to the bond head; and
a gas supplying system connected to the bond head and configured for supplying a bonding gas to the bond head.

10. The bonding apparatus according to claim 9, wherein the bond head comprises a plurality of tube structures configured to pick up the semiconductor chips, and wherein the plurality of tube structures is connected to the vacuum device and the gas supplying system through a plurality of pipe structures.

11. The bonding apparatus according to claim 10, further comprising a plurality of apertures located on the bond head and surrounding the plurality of tube structures, wherein the plurality of apertures is connected to the gas supplying system through a plurality of second pipe structures, and wherein the plurality of apertures is disconnected from the vacuum device.

12. The bonding apparatus according to claim 10, further comprising a gas flow channel located on the bond head and encircling the plurality of tube structures, wherein the gas flow channel is connected to the gas supplying system through a plurality of second pipe structures, and wherein the gas flow channel is disconnected from the vacuum device.

13. The bonding apparatus according to claim 9, further comprising a plurality of gas flow arms attached on side surfaces of the bond head, and wherein the plurality of gas flow arms is connected to the gas supplying system through a plurality of pipe structures.

14. The bonding apparatus according to claim 9, wherein the bonding apparatus further comprises a cover structure, the bond head is located within a space enclosed by the cover structure, and wherein a plurality of gas supplying tubes is located on inner surfaces of the cover structure, and the plurality of gas supplying tubes is connected to the gas supplying system through a plurality of pipe structures.

15. The bonding apparatus according to claim 9, further comprising:
a second bond head configured to pick up a second semiconductor chip from the support structure, and for bonding the second semiconductor chip to the semiconductor wafer on the chuck table, wherein
the vacuum device is further connected to the second bond head and configured for supplying the vacuum to the second bond head.

16. A method of bonding semiconductor chips, comprising:
placing a semiconductor wafer on a chuck table of a bonding apparatus;
driving a bond head of the bonding apparatus for picking up a first semiconductor chip from a support;
driving the bond head for moving the first semiconductor chip to a position located over a first bonding region of the semiconductor wafer; and
bonding the first semiconductor chip to the first bonding region of the semiconductor wafer, and
supplying a bonding gas to the semiconductor wafer through a gas supplying mechanism during the bonding of the first semiconductor chip to the semiconductor wafer.

17. The method according to claim 16, wherein the bonding apparatus further comprises a cover structure, and the bond head is located within a space enclosed by the cover structure, and wherein the method further comprises supplying the bonding gas through the gas supplying mechanism to fill up a space in the cover structure prior to bonding of the first semiconductor chip.

18. The method according to claim 17, wherein the method further comprises:
opening a movable door of the cover structure, and driving the bond head out of the cover structure for picking up the first semiconductor chip from the support;
driving the bond head along with the first semiconductor chip back inside the cover structure and closing the movable door;
supplying the bonding gas through the gas supplying mechanism to fill up the space in the cover structure;
driving the bond head along with the cover structure to the position located over the first bonding region of the semiconductor wafer; and
opening the movable door of the cover structure, and driving the bond head out of the cover structure for bonding the first semiconductor chip to the first bonding region of the semiconductor wafer, and wherein the bond gas inside the cover structure is supplied to the semiconductor wafer.

19. The method according to claim 16, wherein the gas supplying mechanism comprises a plurality of gas flow arms attached on side surfaces of the bond head, and
wherein supplying the bonding gas to the semiconductor wafer through the gas supplying mechanism comprises supplying the bonding gas through the plurality of gas flow arms.

20. The method according to claim 16, wherein the bonding apparatus comprises a vacuum device and a gas flow system connected to the bond head,
wherein driving the bond head of the bonding apparatus for picking up the first semiconductor chip from the support comprises supplying a vacuum to the bond head through the vacuum device for picking up the first semiconductor chip through a vacuum force; and
wherein supplying the bonding gas to the semiconductor wafer comprises supplying the bonding gas to a plurality of apertures located on the bond head through the gas flow system, and so that the bonding gas is supplied from the gas flow system to the semiconductor wafer by passing through the plurality of apertures.
